(19) United States
(12) Patent Application Publication
(10) Pub. No.: US 2026/0332295 A1
(43) Pub. Date: Oct. 22, 2026

(54) LATTICE BASED QUANTIZATION AND CODING FOR FEDERATED AI-ML TRAINING

(71) Applicant: QUALCOMM Incorporated, San Diego, CA (US)

(72) Inventors: Tal OVED, Modiin (IL); Gideon Shlomo KUTZ, Ramat Hasharon (IL); Amit BAR-OR TILLINGER, Tel-Aviv (IL)

(21) Appl. No.: 19/181,115

(22) Filed: Apr. 16, 2025

(51) Int. Cl. H04L 1/00

(52) U.S. Cl. CPC H04L 1/0009

(57) ABSTRACT

A method for wireless communication at a first user equipment (UE) and related apparatus are provided. In the method, the first UE transmits, to a network entity based on a first gradient vector, first communication setup parameters for a lattice-based quantization and coding scheme for communication between the first UE and the network entity. The first UE further receives, from the network entity, first common communication setting parameters for the communication between the first UE and the network entity. The first common communication setting parameters are based on multiple sets of first communication setup parameters respectively from multiple UEs including the first UE. The first UE then transmits, to the network entity, a processed gradient vector based on the first common communication setting parameters and the first gradient vector.

### TECHNICAL FIELD

The present disclosure relates generally to communication systems and, more particularly, to quantization and coding for wireless communication.

### INTRODUCTION

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (e.g., with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard, and some aspects of future wireless communication technologies may be based on aspects of 5G NR. There exists a need for further improvements in 5G NR technology and future wireless communication technologies, such as 6G, among other examples. These improvements may also be applicable to other multi-access technologies and the telecommunication standards that employ these technologies.

### BRIEF SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In an aspect of the disclosure, a method, a computer-readable medium, and an apparatus are provided for wireless communication at a first user equipment (UE). The apparatus may include at least one memory and at least one processor coupled to the at least one memory. Based at least in part on information stored in the at least one memory, the at least one processor may be configured to transmit, to a network entity based on a first gradient vector, first communication setup parameters for a lattice-based quantization and coding scheme for communication between the first UE and the network entity; receive, from the network entity, first common communication setting parameters for the communication between the first UE and the network entity, where the first common communication setting parameters are based on multiple sets of first communication setup parameters respectively from multiple UEs including the first UE; and transmit, to the network entity, a processed gradient vector based on the first common communication setting parameters and the first gradient vector.

In an aspect of the disclosure, a method, a computer-readable medium, and an apparatus are provided for wireless communication at a network entity. The apparatus may include at least one memory and at least one processor coupled to the at least one memory. Based at least in part on information stored in the at least one memory, the at least one processor may be configured to receive, from a first UE of multiple UEs, first communication setup parameters for a lattice-based quantization and coding scheme for communication between the first UE and the network entity, where the first communication setup parameters are based on a first gradient vector; transmit, to the first UE, first common communication setting parameters for the communication between the first UE and the network entity, where the first common communication setting parameters are based on multiple sets of first communication setup parameters respectively from multiple UEs including the first UE; and receive, from the first UE, a processed gradient vector based on the first common communication setting parameters and the first gradient vector.

To the accomplishment of the foregoing and related ends, the one or more aspects may include the features hereinafter fully described and particularly pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a diagram illustrating an example of a wireless communication system and an access network.

FIG. 2A is a diagram illustrating an example of a first frame, in accordance with various aspects of the present disclosure.

FIG. 2B is a diagram illustrating an example of downlink (DL) channels within a subframe, in accordance with various aspects of the present disclosure.

FIG. 2C is a diagram illustrating an example of a second frame, in accordance with various aspects of the present disclosure.

FIG. 2D is a diagram illustrating an example of uplink (UL) channels within a subframe, in accordance with various aspects of the present disclosure.

FIG. 3 is a diagram illustrating an example of a base station and user equipment (UE) in an access network.

FIG. 4 is an illustrative block diagram of an example machine learning (ML) model represented by an artificial neural network (ANN), in accordance with various aspects of the present disclosure.

FIG. 5 is a diagram illustrating an example of an artificial intelligence (AI) and machine learning (ML) (AI/ML) algorithm of a method of wireless communication.

FIG. 6 is a diagram illustrating an example of federated AI training.

FIG. 7 is a diagram illustrating an example of over-the-air (OTA) aggregation for federated AI training.

FIG. 8A is a diagram illustrating an example of two-dimensional cartesian lattice.

FIG. 8B is a diagram illustrating an example of two-dimensional hexagonal lattice.

FIG. 9 shows diagrams illustrating an example of using lattice for quantization and coding of federated learning in accordance with various aspects of the present disclosure.

FIG. 10 is a call flow diagram illustrating a method of wireless communication in accordance with various aspects of the present disclosure.

FIG. 11 is a flowchart illustrating methods of wireless communication at a first UE in accordance with various aspects of the present disclosure.

FIG. 12 is a flowchart illustrating methods of wireless communication at a network entity in accordance with various aspects of the present disclosure.

FIG. 13 is a diagram illustrating an example of a hardware implementation for an example apparatus and/or UE.

FIG. 14 is a diagram illustrating an example of a hardware implementation for an example network entity.

### DETAILED DESCRIPTION

In wireless communication, a base station may utilize federated learning process to train a model, such as an artificial intelligence/machine learning (AI/ML) model that can be used in communication between the base station and multiple user equipment (UE). Federated learning process allows each UE to process its own local data, which is not shared with other UEs, thereby assuring privacy. Example aspects provide a lattice-based quantization and coding method for federated machine learning training in coherent communication schemes, which enhances over-the-air (OTA) aggregation of model parameters by employing structured lattice codes to minimize quantization error and improve error correction.

Various aspects relate generally to wireless communication. Some aspects more specifically relate to quantization and coding for wireless communication. In some examples, a first UE may transmit, to a network entity based on a first gradient vector, first communication setup parameters for a lattice-based quantization and coding scheme for communication between the first UE and the network entity; receive, from the network entity, first common communication setting parameters for the communication between the first UE and the network entity, where the first common communication setting parameters are based on multiple sets of first communication setup parameters respectively from multiple UEs including the first UE; and transmit, to the network entity, a processed gradient vector based on the first common communication setting parameters and the first gradient vector. In some examples, the first gradient vector and the processed gradient vector may be associated with an artificial intelligence/machine learning (AI/ML) model, and the first UE may receive, from the network entity, first model parameters for the AI/ML model. The first gradient vector may be based on the first model parameters. In some examples, the first UE may repeat a model update process for the AI/ML model based on first common communication setting parameters and a current gradient vector. The model update process may include: transmitting, to the network entity, an updated gradient vector based on the first common communication setting parameters and the current gradient vector; receiving, from the network entity, an update to current model parameters for the AI/ML model, where the update to the current model parameters is based on an aggregation of multiple updated gradient vectors respectively from the multiple UEs; and updating the current gradient vector based on the update to the current model parameters.

Particular aspects of the subject matter described in this disclosure can be implemented to realize one or more of the following potential advantages. In some examples, by introducing lattice-based quantization and coding into federated AI/ML OTA training in a coherent wireless communication scheme, the described techniques reduce the quantization error (distortion) during transmission of model parameters, resulting in more accurate aggregation at the base station and improved training convergence. In some examples, by dynamically adapting communication setting parameters (e.g., lattice scaling, code rates) based on channel conditions, the described techniques provide robustness and flexibility in varying wireless conditions, thereby improving the performance of wireless communication.

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Several aspects of telecommunication systems are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer.

While aspects, implementations, and/or use cases are described in this application by illustration to some examples, additional or different aspects, implementations and/or use cases may come about in many different arrangements and scenarios. Aspects, implementations, and/or use cases described herein may be implemented across many differing platform types, devices, systems, shapes, sizes, and packaging arrangements. For example, aspects, implementations, and/or use cases may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described examples may occur. Aspects, implementations, and/or use cases may range a spectrum from chip-level or modular components to non-modular, non-chip-level implementations and further to aggregate, distributed, or original equipment manufacturer (OEM) devices or systems incorporating one or more techniques herein. In some practical settings, devices incorporating described aspects and features may also include additional components and features for implementation and practice of claimed and described aspect. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). Techniques described herein may be practiced in a wide variety of devices, chip-level components, systems, distributed arrangements, aggregated or disaggregated components, end-user devices, etc. of varying sizes, shapes, and constitution.

Deployment of communication systems, such as 5G NR systems, 6G systems, or other communication systems, may be arranged in multiple manners with various components or constituent parts. As an example, in a wireless communication network, a network node, a network entity, a mobility element of a network, a radio access network (RAN) node, a core network node, a network element, or a network equipment, such as a base station (BS), or one or more units (or one or more components) performing base station functionality, may be implemented in an aggregated or disaggregated architecture. For example, a BS (such as a Node B (NB), evolved NB (eNB), NR BS, 5G NB, access point (AP), a transmission reception point (TRP), or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU can be implemented as virtual units, i.e., a virtual central unit (VCU), a virtual distributed unit (VDU), or a virtual radio unit (VRU).

Base station operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

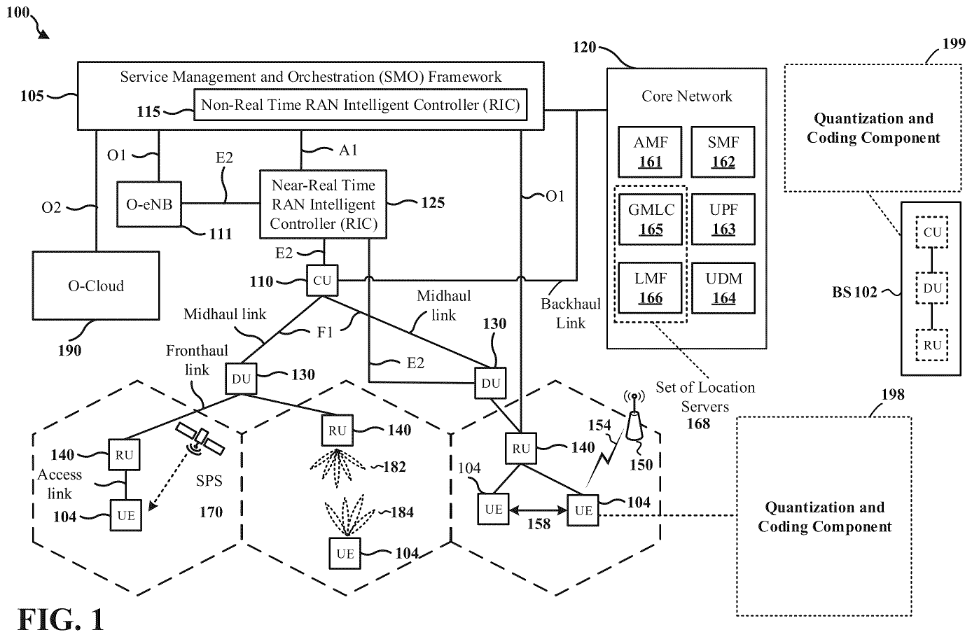

FIG. 1 is a diagram 100 illustrating an example of a wireless communications system and an access network. The illustrated wireless communications system includes a disaggregated base station architecture. The disaggregated base station architecture may include one or more CUs 110 that can communicate directly with a core network 120 via a backhaul link, or indirectly with the core network 120 through one or more disaggregated base station units (such as a Near-Real Time (Near-RT) RAN Intelligent Controller (RIC) 125 via an E2 link, or a Non-Real Time (Non-RT) RIC 115 associated with a Service Management and Orchestration (SMO) Framework 105, or both). A CU 110 may communicate with one or more DUs 130 via respective midhaul links, such as an F1 interface. The DUs 130 may communicate with one or more RUs 140 via respective fronthaul links. The RUs 140 may communicate with respective UEs 104 via one or more radio frequency (RF) access links. In some implementations, the UE 104 may be simultaneously served by multiple RUs 140.

Each of the units, i.e., the CUs 110, the DUs 130, the RUs 140, as well as the Near-RT RICs 125, the Non-RT RICs 115, and the SMO Framework 105, may include one or more interfaces or be coupled to one or more interfaces configured to receive or to transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or to transmit signals over a wired transmission medium to one or more of the other units. Additionally, the units can include a wireless interface, which may include a receiver, a transmitter, or a transceiver (such as an RF transceiver), configured to receive or to transmit signals, or both, over a wireless transmission medium to one or more of the other units.

In some aspects, the CU 110 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 110. The CU 110 may be configured to handle user plane functionality (i.e., Central Unit—User Plane (CU-UP)), control plane functionality (i.e., Central Unit—Control Plane (CU-CP)), or a combination thereof. In some implementations, the CU 110 can be logically split into one or more CU-UP units and one or more CU-CP units. The CU-UP unit can communicate bidirectionally with the CU-CP unit via an interface, such as an E1 interface when implemented in an O-RAN configuration. The CU 110 can be implemented to communicate with the DU 130, as necessary, for network control and signaling.

The DU 130 may correspond to a logical unit that includes one or more base station functions to control the operation of one or more RUs 140. In some aspects, the DU 130 may host one or more of a radio link control (RLC) layer, a medium access control (MAC) layer, and one or more high physical (PHY) layers (such as modules for forward error correction (FEC) encoding and decoding, scrambling, modulation, demodulation, or the like) depending, at least in part, on a functional split, such as those defined by 3GPP. In some aspects, the DU 130 may further host one or more low PHY layers. Each layer (or module) can be implemented with an interface configured to communicate signals with other layers (and modules) hosted by the DU 130, or with the control functions hosted by the CU 110.

Lower-layer functionality can be implemented by one or more RUs 140. In some deployments, an RU 140, controlled by a DU 130, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 140 can be implemented to handle over the air (OTA) communication with one or more UEs 104. In some implementations, real-time and non-real-time aspects of control and user plane communication with the RU(s) 140 can be controlled by the corresponding DU 130. In some scenarios, this configuration can enable the DU(s) 130 and the CU 110 to be implemented in a cloud-based RAN architecture, such as a vRAN architecture.

The SMO Framework 105 may be configured to support RAN deployment and provisioning of non-virtualized and virtualized network elements. For non-virtualized network elements, the SMO Framework 105 may be configured to support the deployment of dedicated physical resources for RAN coverage requirements that may be managed via an operations and maintenance interface (such as an O1 interface). For virtualized network elements, the SMO Framework 105 may be configured to interact with a cloud computing platform (such as an open cloud (O-Cloud) 190) to perform network element life cycle management (such as to instantiate virtualized network elements) via a cloud computing platform interface (such as an O2 interface). Such virtualized network elements can include, but are not limited to, CUs 110, DUs 130, RUs 140 and Near-RT RICs 125. In some implementations, the SMO Framework 105 can communicate with a hardware aspect of a 4G RAN, such as an open eNB (O-eNB) 111, via an O1 interface. Additionally, in some implementations, the SMO Framework 105 can communicate directly with one or more RUs 140 via an O1 interface. The SMO Framework 105 also may include a Non-RT RIC 115 configured to support functionality of the SMO Framework 105.

The Non-RT RIC 115 may be configured to include a logical function that enables non-real-time control and optimization of RAN elements and resources, artificial intelligence (AI)/machine learning (ML) (AI/ML) workflows including model training and updates, or policy-based guidance of applications/features in the Near-RT RIC 125. The Non-RT RIC 115 may be coupled to or communicate with (such as via an AI interface) the Near-RT RIC 125. The Near-RT RIC 125 may be configured to include a logical function that enables near-real-time control and optimization of RAN elements and resources via data collection and actions over an interface (such as via an E2 interface) connecting one or more CUs 110, one or more DUs 130, or both, as well as an O-eNB, with the Near-RT RIC 125.

In some implementations, to generate AI/ML models to be deployed in the Near-RT RIC 125, the Non-RT RIC 115 may receive parameters or external enrichment information from external servers. Such information may be utilized by the Near-RT RIC 125 and may be received at the SMO Framework 105 or the Non-RT RIC 115 from non-network data sources or from network functions. In some examples, the Non-RT RIC 115 or the Near-RT RIC 125 may be configured to tune RAN behavior or performance. For example, the Non-RT RIC 115 may monitor long-term trends and patterns for performance and employ AI/ML models to perform corrective actions through the SMO Framework 105 (such as reconfiguration via 01) or via creation of RAN management policies (such as AI policies).

At least one of the CU 110, the DU 130, and the RU 140 may be referred to as a base station 102. Accordingly, a base station 102 may include one or more of the CU 110, the DU 130, and the RU 140 (each component indicated with dotted lines to signify that each component may or may not be included in the base station 102). The base station 102 provides an access point to the core network 120 for a UE 104. The base station 102 may include macrocells (high power cellular base station) and/or small cells (low power cellular base station). The small cells include femtocells, picocells, and microcells. A network that includes both small cell and macrocells may be known as a heterogeneous network. A heterogeneous network may also include Home Evolved Node Bs (eNBs) (HeNBs), which may provide service to a restricted group known as a closed subscriber group (CSG). The communication links between the RUs 140 and the UEs 104 may include uplink (UL) (also referred to as reverse link) transmissions from a UE 104 to an RU 140 and/or downlink (DL) (also referred to as forward link) transmissions from an RU 140 to a UE 104. The communication links may use multiple-input and multiple-output (MIMO) antenna technology, including spatial multiplexing, beamforming, and/or transmit diversity. The communication links may be through one or more carriers. The base station 102/UEs 104 may use spectrum up to Y MHz (e.g., 5, 10, 15, 20, 100, 400, etc. MHz) bandwidth per carrier allocated in a carrier aggregation of up to a total of Yx MHz (x component carriers) used for transmission in each direction. The carriers may or may not be adjacent to each other. Allocation of carriers may be asymmetric with respect to DL and UL (e.g., more or fewer carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

Certain UEs 104 may communicate with each other using device-to-device (D2D) communication link 158. The D2D communication link 158 may use the DL/UL wireless wide area network (WWAN) spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, Bluetooth™ (Bluetooth is a trademark of the Bluetooth Special Interest Group (SIG)), Wi-Fi™ (Wi-Fi is a trademark of the Wi-Fi Alliance) based on the Institute of Electrical and Electronics Engineers (IEEE) 802.11 standard, LTE, or NR.

The wireless communications system may further include a Wi-Fi AP 150 in communication with UEs 104 (also referred to as Wi-Fi stations (STAs)) via communication link 154, e.g., in a 5 GHz unlicensed frequency spectrum or the like. When communicating in an unlicensed frequency spectrum, the UEs 104/AP 150 may perform a clear channel assessment (CCA) prior to communicating in order to determine whether the channel is available.

The electromagnetic spectrum is often subdivided, based on frequency/wavelength, into various classes, bands, channels, etc. Two initial operating bands have been identified as frequency range designations FR1 (410 MHz-7.125 GHz) and FR2 (24.25 GHz-52.6 GHz). Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. An operating band for these mid-band frequencies may have the frequency range designation FR3 (7.125 GHz-24.25 GHz), for example. Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation, or other wireless communication operation, beyond 52.6 GHz. For example, three higher operating bands have been identified as frequency range designations FR2-2 (52.6 GHz-71 GHz), FR4 (71 GHz-114.25 GHz), and FR5 (114.25 GHz-300 GHz). Each of these higher frequency bands falls within the EHF band.

With the above aspects in mind, unless specifically stated otherwise, the term “sub-6 GHz” or the like if used herein may broadly represent frequencies that may be less than 6 GHz, may be within FR1, or may include mid-band frequencies. Further, unless specifically stated otherwise, the term “millimeter wave” or the like if used herein may broadly represent frequencies that may include mid-band frequencies, may be within FR2, FR4, FR2-2, and/or FR5, or may be within the EHF band.

The base station 102 and the UE 104 may each include a plurality of antennas, such as antenna elements, antenna panels, and/or antenna arrays to facilitate beamforming. The base station 102 may transmit a beamformed signal 182 to the UE 104 in one or more transmit directions. The UE 104 may receive the beamformed signal from the base station 102 in one or more receive directions. The UE 104 may also transmit a beamformed signal 184 to the base station 102 in one or more transmit directions. The base station 102 may receive the beamformed signal from the UE 104 in one or more receive directions. The base station 102/UE 104 may perform beam training to determine the best receive and transmit directions for each of the base station 102/UE 104. The transmit and receive directions for the base station 102 may or may not be the same. The transmit and receive directions for the UE 104 may or may not be the same.

The base station 102 may include and/or be referred to as a gNB, Node B, eNB, an access point, a base transceiver station, a radio base station, a radio transceiver, a transceiver function, a basic service set (BSS), an extended service set (ESS), a TRP, network node, network entity, network equipment, or some other suitable terminology. The base station 102 can be implemented as an integrated access and backhaul (IAB) node, a relay node, a sidelink node, an aggregated (monolithic) base station with a baseband unit (BBU) (including a CU and a DU) and an RU, or as a disaggregated base station including one or more of a CU, a DU, and/or an RU. The set of base stations, which may include disaggregated base stations and/or aggregated base stations, may be referred to as next generation (NG) RAN (NG-RAN).

The core network 120 may include an Access and Mobility Management Function (AMF) 161, a Session Management Function (SMF) 162, a User Plane Function (UPF) 163, a Unified Data Management (UDM) 164, one or more location servers 168, and other functional entities. The AMF 161 is the control node that processes the signaling between the UEs 104 and the core network 120. The AMF 161 supports registration management, connection management, mobility management, and other functions. The SMF 162 supports session management and other functions. The UPF 163 supports packet routing, packet forwarding, and other functions. The UDM 164 supports the generation of authentication and key agreement (AKA) credentials, user identification handling, access authorization, and subscription management. The one or more location servers 168 are illustrated as including a Gateway Mobile Location Center (GMLC) 165 and a Location Management Function (LMF) 166. However, generally, the one or more location servers 168 may include one or more location/positioning servers, which may include one or more of the GMLC 165, the LMF 166, a position determination entity (PDE), a serving mobile location center (SMLC), a mobile positioning center (MPC), or the like. The GMLC 165 and the LMF 166 support UE location services. The GMLC 165 provides an interface for clients/applications (e.g., emergency services) for accessing UE positioning information. The LMF 166 receives measurements and assistance information from the NG-RAN and the UE 104 via the AMF 161 to compute the position of the UE 104. The NG-RAN may utilize one or more positioning methods in order to determine the position of the UE 104. Positioning the UE 104 may involve signal measurements, a position estimate, and an optional velocity computation based on the measurements. The signal measurements may be made by the UE 104 and/or the base station 102 serving the UE 104. The signals measured may be based on one or more of a satellite positioning system (SPS) 170 (e.g., one or more of a Global Navigation Satellite System (GNSS), global position system (GPS), non-terrestrial network (NTN), or other satellite position/location system), LTE signals, wireless local area network (WLAN) signals, Bluetooth signals, a terrestrial beacon system (TBS), sensor-based information (e.g., barometric pressure sensor, motion sensor), NR enhanced cell ID (NR E-CID) methods, NR signals (e.g., multi-round trip time (Multi-RTT), DL angle-of-departure (DL-AoD), DL time difference of arrival (DL-TDOA), UL time difference of arrival (UL-TDOA), and UL angle-of-arrival (UL-AoA) positioning), and/or other systems/signals/sensors.

Examples of UEs 104 include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (e.g., parking meter, gas pump, toaster, vehicles, heart monitor, etc.). The UE 104 may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

Referring again to FIG. 1, in certain aspects, the UE 104 may include quantization and coding component 198. The quantization and coding component 198 may be configured to transmit, to a network entity based on a first gradient vector, first communication setup parameters for a lattice-based quantization and coding scheme for communication between the first UE and the network entity; receive, from the network entity, first common communication setting parameters for the communication between the first UE and the network entity, where the first common communication setting parameters are based on multiple sets of first communication setup parameters respectively from multiple UEs including the first UE; and transmit, to the network entity, a processed gradient vector based on the first common communication setting parameters and the first gradient vector. In certain aspects, the base station 102 may include the quantization and coding component 199. The quantization and coding component 199 may be configured to receive, from a first UE of multiple UEs, first communication setup parameters for a lattice-based quantization and coding scheme for communication between the first UE and the network entity, where the first communication setup parameters are based on a first gradient vector; transmit, to the first UE, first common communication setting parameters for the communication between the first UE and the network entity, where the first common communication setting parameters are based on multiple sets of first communication setup parameters respectively from multiple UEs including the first UE; and receive, from the first UE, a processed gradient vector based on the first common communication setting parameters and the first gradient vector. Although the following description may give examples based on 5G NR to illustrate concepts relating to wireless communication, the concepts described herein may be applicable to other similar areas, such as LTE, LTE-A, CDMA, GSM, 6G, and other wireless technologies.

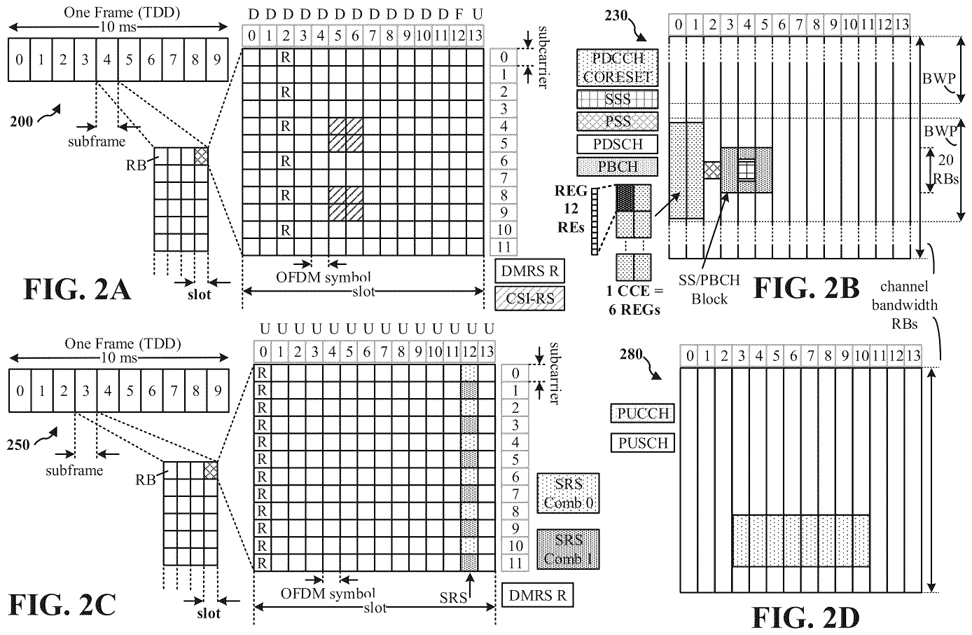

FIG. 2A is a diagram 200 illustrating an example of a first subframe within a frame structure. FIG. 2B is a diagram 230 illustrating an example of DL channels within a subframe. FIG. 2C is a diagram 250 illustrating an example of a second subframe within a frame structure. FIG. 2D is a diagram 280 illustrating an example of UL channels within a subframe. The examples in FIGS. 2A-2D show example aspects of a frame structure based on 5G NR to illustrate the concept of a frame structure and wireless communication based on a frame structure. Various aspects described in connection with FIGS. 2A-2D may also be used in connection with other wireless communication technologies, such as 6G among other examples. The frequency division duplexed (FDD) in which for a particular set of subcarriers (carrier system bandwidth), subframes within the set of subcarriers are dedicated for either DL or UL, or may be time division duplexed (TDD) in which for a particular set of subcarriers (carrier system bandwidth), subframes within the set of subcarriers are dedicated for both DL and UL. In the examples provided by FIGS. 2A, 2C, the 5G NR frame structure is assumed to be TDD, with subframe 4 being configured with slot format 28 (with mostly DL), where D is DL, U is UL, and F is flexible for use between DL/UL, and subframe 3 being configured with slot format 1 (with all UL). While subframes 3, 4 are shown with slot formats 1, 28, respectively, any particular subframe may be configured with any of the various available slot formats 0-61. Slot formats 0, 1 are all DL, UL, respectively. Other slot formats 2-61 include a mix of DL, UL, and flexible symbols. UEs are configured with the slot format (dynamically through DL control information (DCI), or semi-statically/statically through radio resource control (RRC) signaling) through a received slot format indicator (SFI). Note that the description infra applies also to a 5G NR frame structure that is TDD.

FIGS. 2A-2D illustrate a frame structure, and the aspects of the present disclosure may be applicable to other wireless communication technologies, which may have a different frame structure and/or different channels. A frame (10 ms) may be divided into 10 equally sized subframes (1 ms). Each subframe may include one or more time slots. Subframes may also include mini-slots, which may include 7, 4, or 2 symbols. Each slot may include 14 or 12 symbols, depending on whether the cyclic prefix (CP) is normal or extended. For normal CP, each slot may include 14 symbols, and for extended CP, each slot may include 12 symbols. The symbols on DL may be CP orthogonal frequency division multiplexing (OFDM) (CP-OFDM) symbols. The symbols on UL may be CP-OFDM symbols (for high throughput scenarios) or discrete Fourier transform (DFT) spread OFDM (DFT-s-OFDM) symbols (for power limited scenarios; limited to a single stream transmission). The number of slots within a subframe is based on the CP and the numerology. The numerology defines the subcarrier spacing (SCS) (see Table 1). The symbol length/duration may scale with 1/SCS.

TABLE 1
Numerology, SCS, and CP

| | SCS | Cyclic |
|---|---|---|
| μ | Δf = 2^{μ} · 15[kHz] | prefix |
| 0 | 15 | Normal |
| 1 | 30 | Normal |
| 2 | 60 | Normal, |
| | | Extended |
| 3 | 120 | Normal |
| 4 | 240 | Normal |
| 5 | 480 | Normal |
| 6 | 960 | Normal |

For normal CP (14 symbols/slot), different numerologies μ 0 to 4 allow for 1, 2, 4, 8, and 16 slots, respectively, per subframe. For extended CP, the numerology 2 allows for 4 slots per subframe. Accordingly, for normal CP and numerology μ, there are 14 symbols/slot and 2^{μ} slots/subframe. The subcarrier spacing may be equal to 2*15 kHz, where μ is the numerology 0 to 4. As such, the numerology μ=0 has a subcarrier spacing of 15 kHz and the numerology μ=4 has a subcarrier spacing of 240 kHz. The symbol length/duration is inversely related to the subcarrier spacing. FIGS. 2A-2D provide an example of normal CP with 14 symbols per slot and numerology μ=2 with 4 slots per subframe. The slot duration is 0.25 ms, the subcarrier spacing is 60 kHz, and the symbol duration is approximately 16.67 s. Within a set of frames, there may be one or more different bandwidth parts (BWPs) (see FIG. 2B) that are frequency division multiplexed. Each BWP may have a particular numerology and CP (normal or extended).

A resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 2A, some of the REs carry reference (pilot) signals (RS) for the UE. The RS may include demodulation RS (DM-RS) (indicated as R for one particular configuration, but other DM-RS configurations are possible) and channel state information reference signals (CSI-RS) for channel estimation at the UE. The RS may also include beam measurement RS (BRS), beam refinement RS (BRRS), and phase tracking RS (PT-RS).

FIG. 2B illustrates an example of various DL channels within a subframe of a frame. The physical downlink control channel (PDCCH) carries DCI within one or more control channel elements (CCEs) (e.g., 1, 2, 4, 8, or 16 CCEs), each CCE including six RE groups (REGs), each REG including 12 consecutive REs in an OFDM symbol of an RB. A PDCCH within one BWP may be referred to as a control resource set (CORESET). A UE is configured to monitor PDCCH candidates in a PDCCH search space (e.g., common search space, UE-specific search space) during PDCCH monitoring occasions on the CORESET, where the PDCCH candidates have different DCI formats and different aggregation levels. Additional BWPs may be located at greater and/or lower frequencies across the channel bandwidth. A primary synchronization signal (PSS) may be within symbol 2 of particular subframes of a frame. The PSS is used by a UE 104 to determine subframe/symbol timing and a physical layer identity. A secondary synchronization signal (SSS) may be within symbol 4 of particular subframes of a frame. The SSS is used by a UE to determine a physical layer cell identity group number and radio frame timing. Based on the physical layer identity and the physical layer cell identity group number, the UE can determine a physical cell identifier (PCI). Based on the PCI, the UE can determine the locations of the DM-RS. The physical broadcast channel (PBCH), which carries a master information block (MIB), may be logically grouped with the PSS and SSS to form a synchronization signal (SS)/PBCH block (also referred to as SS block (SSB)). The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry DM-RS (indicated as R for one particular configuration, but other DM-RS configurations are possible) for channel estimation at the base station. The UE may transmit DM-RS for the physical uplink control channel (PUCCH) and DM-RS for the physical uplink shared channel (PUSCH). The PUSCH DM-RS may be transmitted in the first one or two symbols of the PUSCH. The PUCCH DM-RS may be transmitted in different configurations depending on whether short or long PUCCHs are transmitted and depending on the particular PUCCH format used. The UE may transmit sounding reference signals (SRS). The SRS may be transmitted in the last symbol of a subframe. The SRS may have a comb structure, and a UE may transmit SRS on one of the combs. The SRS may be used by a base station for channel quality estimation to enable frequency-dependent scheduling on the UL.

FIG. 2D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and hybrid automatic repeat request (HARQ) acknowledgment (ACK) (HARQ-ACK) feedback (i.e., one or more HARQ ACK bits indicating one or more ACK and/or negative ACK (NACK)). The PUSCH carries data, and may additionally be used to carry a buffer status report (BSR), a power headroom report (PHR), and/or UCI.

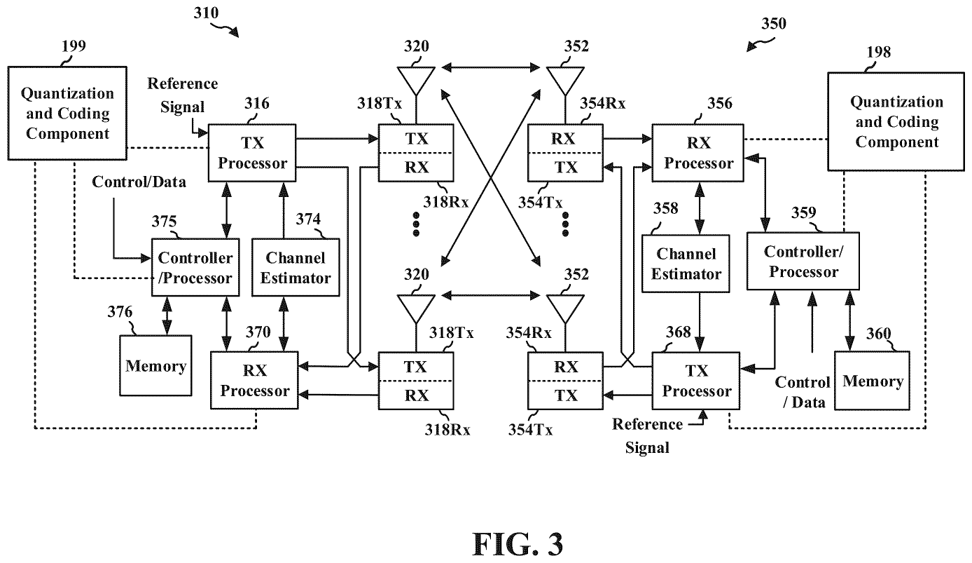

FIG. 3 is a block diagram of a base station 310 in communication with a UE 350 in an access network. In the DL, Internet protocol (IP) packets may be provided to a controller/processor 375. The controller/processor 375 implements layer 3 and layer 2 functionality. Layer 3 includes a radio resource control (RRC) layer, and layer 2 includes a service data adaptation protocol (SDAP) layer, a packet data convergence protocol (PDCP) layer, a radio link control (RLC) layer, and a medium access control (MAC) layer. The controller/processor 375 provides RRC layer functionality associated with broadcasting of system information (e.g., MIB, SIBs), RRC connection control (e.g., RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (e.g., binary phase-shift keying (BPSK), quadrature phase-shift keying (QPSK), M-phase-shift keying (M-PSK), M-quadrature amplitude modulation (M-Q_{Λ}M)). The coded and modulated symbols may then be split into parallel streams. Each stream may then be mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal and/or channel condition feedback transmitted by the UE 350. Each spatial stream may then be provided to a different antenna 320 via a separate transmitter 318Tx. Each transmitter 318Tx may modulate a radio frequency (RF) carrier with a respective spatial stream for transmission.

At the UE 350, each receiver 354Rx receives a signal through its respective antenna 352. Each receiver 354Rx recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 then converts the OFDM symbol stream from the time-domain to the frequency domain using a Fast Fourier Transform (FFT). The frequency domain signal includes a separate OFDM symbol stream for each subcarrier of the OFDM signal. The symbols on each subcarrier, and the reference signal, are recovered and demodulated by determining the most likely signal constellation points transmitted by the base station 310. These soft decisions may be based on channel estimates computed by the channel estimator 358. The soft decisions are then decoded and deinterleaved to recover the data and control signals that were originally transmitted by the base station 310 on the physical channel. The data and control signals are then provided to the controller/processor 359, which implements layer 3 and layer 2 functionality.

The controller/processor 359 can be associated with at least one memory 360 that stores program codes and data. The at least one memory 360 may be referred to as a computer-readable medium. In the UL, the controller/processor 359 provides demultiplexing between transport and logical channels, packet reassembly, deciphering, header decompression, and control signal processing to recover IP packets. The controller/processor 359 is also responsible for error detection using an ACK and/or NACK protocol to support HARQ operations.

Similar to the functionality described in connection with the DL transmission by the base station 310, the controller/processor 359 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the base station 310 may be used by the TX processor 368 to select the appropriate coding and modulation schemes, and to facilitate spatial processing. The spatial streams generated by the TX processor 368 may be provided to different antenna 352 via separate transmitters 354Tx. Each transmitter 354Tx may modulate an RF carrier with a respective spatial stream for transmission.

The UL transmission is processed at the base station 310 in a manner similar to that described in connection with the receiver function at the UE 350. Each receiver 318Rx receives a signal through its respective antenna 320. Each receiver 318Rx recovers information modulated onto an RF carrier and provides the information to a RX processor 370.

The controller/processor 375 can be associated with at least one memory 376 that stores program codes and data. The at least one memory 376 may be referred to as a computer-readable medium. In the UL, the controller/processor 375 provides demultiplexing between transport and logical channels, packet reassembly, deciphering, header decompression, control signal processing to recover IP packets. The controller/processor 375 is also responsible for error detection using an ACK and/or NACK protocol to support HARQ operations.

At least one of the TX processor 368, the RX processor 356, and the controller/processor 359 may be configured to perform aspects in connection with the quantization and coding component 198 of FIG. 1.

At least one of the TX processor 316, the RX processor 370, and the controller/processor 375 may be configured to perform aspects in connection with the quantization and coding component 199 of FIG. 1.

Some aspects and techniques as described herein may be implemented, at least in part, using an artificial intelligence (AI) program, such as a program that includes a machine learning (ML) or artificial neural network (ANN) model. An example ML model may include mathematical representations or define computing capabilities for making inferences from input data based on patterns or relationships identified in the input data. As used herein, the term “inferences” can include one or more decisions, predictions, determinations, or values, which may represent outputs of the ML model. The computing capabilities may be defined in terms of certain model parameters of the ML model, such as weights and biases. Weights may indicate relationships between certain input data and certain outputs of the ML model, and biases are offsets that may indicate a starting point for the outputs of the ML model. An example ML model operating on input data may start at an initial output based on the biases and then update its output based on a combination of the input data and the weights.

In some aspects, an ML model, also referred to as an AI/ML model in some aspects, may be configured to provide computing capabilities for wireless communications. Such an ML model may be configured with weights and biases to perform tasks such as beam prediction, CSI prediction, CSI compression/decompression, interference prediction, positioning, sensing, scheduling and resource selection, and/or reference signal design and optimization, among other examples.

ML models may be deployed in one or more devices (for example, network entities and user equipment (UE)) and may be configured to enhance various aspects of a wireless communication system. For example, an ML model may be trained to identify patterns or relationships in data corresponding to a network, a device, an air interface, or the like. An ML model may support operational decisions relating to one or more aspects associated with wireless communications devices, networks, or services. For example, an ML model may be utilized for supporting or improving aspects such as signal coding/decoding, network routing, energy conservation, transceiver circuitry controls, frequency synchronization, timing synchronization, channel state estimation, channel equalization, channel state feedback, modulation, demodulation, device positioning, beamforming, load balancing, operations and management functions, security, etc.

ML models may be characterized in terms of types of learning that generate specific types of learned models that perform specific types of tasks. For example, different types of machine learning include supervised learning, unsupervised learning, semi-supervised learning, reinforcement learning, deep learning, etc. ML models may be used to perform different tasks, such as classification or regression, where classification refers to determining one or more discrete output values from a set of predefined output values, and regression refers to determining continuous values that are not bounded by predefined output values. Some example ML models configured for performing such tasks include ANNs such as convolutional neural networks (CNNs) and recurrent neural networks (RNNs), transformers, diffusion models, regression analysis models (such as statistical models), large language models (LLMs), decision tree learning (such as predictive models), support vector networks (SVMs), and probabilistic graphical models (such as a Bayesian network), etc.

The description herein illustrates, by way of some examples, how one or more tasks or problems in wireless communications may benefit from the application of one or more ML models for the prediction of one or more channel characteristics associated with a second set of resources using measurement of the aperiodic reference signal on a first set of resources based on a first mapping pattern. The first mapping pattern maps the first set of resources to the second set of resources, and the first mapping pattern and a second mapping pattern associated with an initial training meet one or more of a spatial domain consistency condition or a temporal domain consistency condition. To facilitate the discussion, an ML model configured using an ANN is used, but other types of ML models may be used instead of an ANN. Hence, unless expressly recited, subject matter regarding an ML model is not intended to be limited to an ANN solution. Unless otherwise specifically stated, terms such “AI/ML model,” “ML model,” “trained ML mode,” “ANN,” “model,” “algorithm,” or the like are intended to be interchangeable.

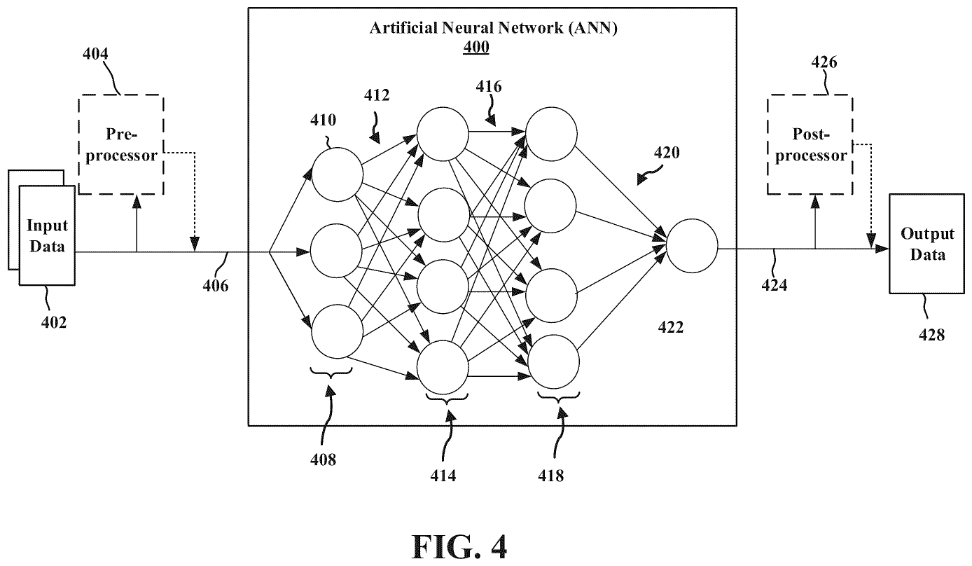

FIG. 4 is an illustrative block diagram of an example machine learning (ML) model represented by an artificial neural network (ANN) 400. ANN 400 may receive input data 406, which may include one or more bits of data 402, pre-processed data output from pre-processor 404 (optional), or some combination thereof. Here, data 402 may include training data, verification data, application-related data, or the like, based, for example, on the stage of deployment of ANN 400. Pre-processor 404 may be included within ANN 400 in some other implementations. Pre-processor 404 may, for example, process all or a portion of data 402, which may result in some of data 402 being changed, replaced, deleted, etc. In some implementations, pre-processor 404 may add additional data to data 402. In some implementations, the pre-processor 404 may be an ML model, such as an ANN. As an example, the input for traffic classification may include traffic information or traffic pattern information. In other examples, the input may be different. For example, for beam prediction, the input may be measurements performed on a set-B of beams. For CSI prediction, compression, or decompression, the input may include one or more CSI measurements. For a model trained for interference prediction, the input may include one or more interference measurements, or other information that may enable the model to predict interference. For positioning, sensing, scheduling and resource selection, and/or reference signal design and optimization, the input may be different.

The ANN 400 includes at least one first layer 408 of artificial neurons 410 to process input data 406 and provide resulting first layer data via connections or “edges” such as edges 412 to at least a portion of at least one second layer 414. Second layer 414 processes data received via edges 412 and provides second layer output data via edges 416 to at least a portion of at least one third layer 418. Third layer 418 processes data received via edges 416 and provides third layer output data via edges 420 to at least a portion of a final layer 422, including one or more neurons to provide output data 424. All or part of output data 424 may be further processed in some manner by (optional) post-processor 426. Thus, in certain examples, ANN 400 may provide output data 428 that is based on output data 424, post-processed data output from post-processor 426, or some combination thereof. In an example where the ML model is used to classify traffic, the output may include an inference of a traffic type. In examples where the ML model is used for beam prediction, the output may include a set of resource (e.g., beam) predictions for Set-A beams. A base station or UE may then select a beam for use in transmission and/or reception based on the beam predictions for the Set-A beams output from the AI/ML model. In an ML model may be trained for CSI prediction, the output may be a predicted CSI measurement that may be used for future communication. For CSI compression, the input may be CSI to be reported, and the output may include a compressed CSI that can be signaled using reduced overhead. For CSI decompression, the input may be a compressed CSI based on a corresponding model, and the output may be a decompressed CSI with the original CSI prior to compression. For interference prediction, the output may be a prediction of interference for one or more resources. For positioning, the output may be a position prediction. For scheduling and resource selection, the output may be an indication of resources that will allow for more accurate communication and/or more efficient scheduling. For reference signal design and optimization, the output may identify a reference signal or one or more parameters for a reference signal for use by a UE or a network.

Post-processor 426 may be included within ANN 400 in some other implementations. Post-processor 426 may, for example, process all or a portion of output data 424, which may result in output data 428 being different, at least in part, from output data 424, as a result of data being changed, replaced, deleted, etc. In some implementations, post-processor 426 may be configured to add additional data to output data 424. In this example, second layer 414 and third layer 418 represent intermediate or hidden layers that may be arranged in a hierarchical or other like structure. Although not explicitly shown, there may be one or more further intermediate layers between the second layer 414 and the third layer 418. In some implementations, the post-processor 426 may be an ML model, such as an ANN.

The structure and training of artificial neurons 410 in the various layers may be tailored to the specific requirements of an application. Within a given layer, such as first layer 408, second layer 414, or third layer 418 of ANN 400, some or all of the neurons may be configured to process information provided to the layer and output corresponding transformed information from the layer. For example, transformed information from a layer may represent a weighted summation of the input information associated with or otherwise based on a non-linear activation function or other activation function used to “activate” the artificial neurons of the next layer. Artificial neurons in such a layer may be activated by or be responsive to parameters such as the previously described weights and biases of ANN 400. The weights and biases of ANN 400 may be adjusted during a training process or during operation of ANN 400. The weights of the various artificial neurons may control the strength of connections between layers or artificial neurons, while the biases may control the direction of connections between the layers or artificial neurons. An activation function may select or determine whether an artificial neuron transmits its output to the next layer or not in response to its received data.

Different activation functions may be used to model different types of non-linear relationships. By introducing non-linearity into an ML model, an activation function allows the configuration for the ML model to change in response to identifying or detecting complex patterns and relationships in the input data 406. Some non-exhaustive example activation functions include a sigmoid based activation function, a hyperbolic tangent (tanh) based activation function, a convolutional activation function, up-sampling, pooling, and a rectified linear unit (ReLU) based activation function.

Training of an ML model, such as ANN 400, may be conducted using training data. Training data may include one or more datasets that ANN 400 may use to identify patterns or relationships. Training data may represent various types of information, including written, visual, audio, environmental context, operational properties, etc. During training, the parameters (such as the weights and biases) of artificial neurons 410 may be changed, such as to minimize or otherwise reduce a loss function or a cost function. A training process may be repeated multiple times to fine-tune ANN 400 with each iteration.

Various ANN model structures are available for consideration. For example, in a feedforward ANN structure, each artificial neuron 410 in layer 414 receives information from the previous layer (such as one or more artificial neurons 410 in layer 408) and produces information for the next layer (such as one or more artificial neurons 410 in layer 418). In a convolutional ANN structure, some layers may be organized into filters that extract features from data, such as the training data or the input data. In a recurrent ANN structure, some layers may have connections that allow for the processing of data across time, such as for processing information having a temporal structure, such as time series data forecasting.

In an autoencoder ANN structure, compact representations of data may be processed and the model trained to predict or potentially reconstruct original data from a reduced set of features. An autoencoder ANN structure may be useful for tasks related to dimensionality reduction and data compression.

A generative adversarial ANN structure may include a generator ANN and a discriminator ANN that are trained to compete with each other. Generative-adversarial networks (GANs) are ANN structures that may be useful for tasks relating to generating synthetic data or improving the performance of other models.

A transformer ANN structure makes use of attention mechanisms that may enable the model to process input sequences in a parallel and efficient manner. An attention mechanism allows the model to focus on different parts of the input sequence at different times. Attention mechanisms may be implemented using a series of layers known as attention layers to compute weighted sums of input features based on a similarity between different elements of the input sequence. A transformer ANN structure may include a series of feedforward ANN layers whose configurations may change in response to identifying non-linear relationships between the input and output sequences, which may also be referred to as a process of “learning” by the ANN layers. The output of a transformer ANN structure may be obtained by applying a linear transformation to the output of a final attention layer. A transformer ANN structure may be of particular use for tasks that involve sequence modeling, or other like processing.

Another example type of ANN structure is a model with one or more invertible layers. Models of this type may be inverted or “unwrapped” to reveal the input data that was used to generate the output of a layer. Other example types of ANN model structures include fully connected neural networks (FCNNs) and long short-term memory (LSTM) networks.

ANN 400 or other ML models may be implemented in various types of processing circuits along with memory and applicable instructions therein. For example, general-purpose hardware circuits, such as one or more central processing units (CPUs), one or more graphics processing units (GPUs), or suitable combinations thereof, may be employed to implement a model. In some implementations, one or more tensor processing units (TPUs), neural processing units (NPUs), or other special-purpose processors, field-programmable gate arrays (FPGAs), application-specific integrated circuits (ASICs), or the like may also be employed. In some implementations, the ML model may be implemented by an NPU or a TPU embedded in a system on chip (SoC) along with other components, such as one or more CPUs, GPUs, etc. A SoC includes several components manufactured on a shared semiconductor substrate. The NPU or TPU may be controlled by the one or more CPUs by configuring the ML model implemented by the NPU or TPU with weights and biases, providing certain training data to the ML model to configure the ML model, or providing input data to the ML model to obtain related inferences. The one or more CPUs may also receive the inferences and be configured to perform certain actions based on the inferences produced by the ML model. The actions performed by the one or more CPUs may include sending commands to other components of the SoC or components external to the SoC to perform certain actions. For example, the CPU may send commands to an RF transceiver based on the outputs or inferences obtained from an ML model to cause the RF transceiver to operate on a wireless network in accordance with the ML model.

In some examples, an ML model may be trained prior to, or at some point following, the operation of the ML model, such as ANN 400, on input data. When training the ML model, information in the form of applicable training data may be gathered or otherwise created for use in training an ANN accordingly. For example, training data may be gathered or otherwise created regarding information associated with received/transmitted signal strengths, interference, and resource usage data, as well as any other relevant data that might be useful for training a model to address one or more problems or issues in a communication system. In certain instances, all or part of the training data may originate in a user equipment (UE) or other device in a wireless communication system, or one or more network entities, or aggregated from multiple sources (such as a UE and a network entity/entities, one or more other UEs, the Internet, or the like). For example, wireless network architectures, such as self-organizing networks (SON) or mobile drive test (MDT) networks, may be adapted to support the collection of data for ML model applications. In another example, training data may be generated or collected online, offline, or both online and offline by a UE, network entity, or other device(s), and all or part of such training data may be transferred or shared (in real or near-real time), such as through store and forward functions or the like.

Offline training may refer to creating and using a static training dataset, such as in a batched manner, whereas online training may refer to the real-time collection and use of training data. For example, an ML model at a network device (such as a UE) may be trained or fine-tuned using online or offline training. For offline training, data collection and training can occur in an offline manner at the network side (such as at a base station or other network entity) or at the UE side. For online training, the training of a UE-side ML model may be performed locally at the UE or by a server device (such as a server hosted by a UE vendor) in a real-time or near-real-time manner based on data provided to the server device from the UE. In certain instances, all or part of the training data may be shared within a wireless communication system or even shared (or obtained from) outside of the wireless communication system.

Once an ANN has been configured by setting parameters, including weights and biases, from training data, the ANN's performance may be evaluated. In some scenarios, evaluation/verification tests may use a validation dataset, which may include data not in the training data, to compare the model's performance to baseline or other benchmark information. The ANN configuration may be further refined, for example, by changing its architecture, retraining it on the data, or using different optimization techniques, etc.

As part of a training process, parameters affecting the functioning of the artificial neurons and layers may be adjusted. For example, backpropagation techniques may be used to train an ANN by iteratively adjusting weights or biases of certain artificial neurons associated with errors between a predicted output of the model and a desired output that may be known or otherwise deemed acceptable. Backpropagation may include a forward pass, a loss function, a backward pass, and a parameter update that may be performed in training iteration. The process may be repeated for a certain number of iterations for each set of training data until the weights of the artificial neurons/layers are adequately tuned.

Backpropagation techniques associated with a loss function may measure how well a model is able to predict a desired output for a given input. An optimization algorithm may be used during a training process to adjust weights and biases to reduce or minimize the loss function, which can improve the performance of the model. There are a variety of optimization algorithms that may be used along with backpropagation techniques or other training techniques. Some initial examples include a gradient descent based optimization algorithm and a stochastic gradient descent based optimization algorithm. A stochastic gradient descent technique may be used to adjust weights/biases in order to minimize or otherwise reduce a loss function. A mini-batch gradient descent technique, which is a variant of gradient descent, may involve updating weights/biases using a small batch of training data rather than the entire dataset. A momentum technique may accelerate an optimization process by adding a momentum term to update or otherwise affect certain weights/biases.

An adaptive learning rate technique may adjust the learning rate of an optimization algorithm associated with one or more characteristics of the training data. A batch normalization technique may be used to normalize inputs to a model in order to stabilize a training process and potentially improve the performance of the model. A “dropout” technique may be used to randomly drop out some of the artificial neurons from a model during a training process, for example, in order to reduce overfitting and potentially improve the generalization of the model. An “early stopping” technique may be used to stop an ongoing training process early, such as when a performance of the model using a validation dataset starts to degrade.

Another example technique includes data augmentation to generate additional training data by applying transformations to all or part of the training information. A transfer learning technique may be used which involves using a pre-trained model as a starting point for training a new model, which may be useful when training data is limited or when there are multiple tasks that are related to each other. A multi-task learning technique may be used which involves training a model to perform multiple tasks simultaneously to potentially improve the performance of the model on one or more of the tasks. Hyperparameters or the like may be input and applied during a training process in certain instances.

Another example technique that may be useful with regard to an ANN is a “pruning” technique. A pruning technique, which may be performed during a training process or after a model has been trained, involves the removal of unnecessary or less necessary, or possibly redundant features from a model. In certain instances, a pruning technique may reduce the complexity of a model or improve the efficiency of a model without undermining the intended performance of the model.

Pruning techniques may be particularly useful in the context of wireless communication, where the available resources (such as power and bandwidth) may be limited. Some example pruning techniques include a weight pruning technique, a neuron pruning technique, a layer pruning technique, a structural pruning technique, and a dynamic pruning technique. Pruning techniques may, for example, reduce the amount of data corresponding to a model that is transmitted or stored. Weight pruning techniques may involve removing some of the weights from a model. Neuron pruning techniques may involve removing some neurons from a model. Layer pruning techniques may involve removing some layers from a model. Structural pruning techniques may involve removing some connections between neurons in a model. Dynamic pruning techniques may involve adapting a pruning strategy of a model associated with one or more characteristics of the data or the environment. For example, in certain wireless communication devices, a dynamic pruning technique may more aggressively prune a model for use in a low-power or low-bandwidth environment and less aggressively prune the model for use in a high-power or high-bandwidth environment. In certain example implementations, pruning techniques may also be applied to training data, for example, to remove outliers. In some implementations, pre-processing techniques directed to all or part of a training dataset may improve model performance or promote faster convergence of a model. For example, training data may be pre-processed to change or remove unnecessary data, extraneous data, incorrect data, or otherwise identifiable data. Such pre-processed training data may, for example, lead to a reduction in potential overfitting or otherwise improve the performance of the trained model.

One or more of the example training techniques presented above may be employed as part of a training process. Some example training processes that may be used to train an ANN include supervised learning, unsupervised learning, semi-supervised learning, and reinforcement learning techniques. With supervised learning, a model is trained on a labeled training dataset, where the input data is accompanied by a correct or otherwise acceptable output. With unsupervised learning, a model is trained on an unlabeled training dataset, such that the model will learn to identify patterns and relationships in the data without the explicit guidance of a labeled training dataset. With semi-supervised learning, a model is trained using some combination of supervised and unsupervised learning processes, for example, when the amount of labeled data is somewhat limited. With reinforcement learning, a model may learn from interactions with its operation/environment, such as in the form of feedback akin to rewards or penalties. Reinforcement learning may be particularly beneficial when used to improve or attempt to optimize the behavior of a model deployed in a dynamically changing environment, such as a wireless communication network.

Distributed, shared, or collaborative learning techniques may be used for the training process. For example, techniques such as federated learning may be used to decentralize the training process and rely on multiple devices, network entities, or organizations for training various versions or copies of an ML model without relying on a centralized training mechanism. Federated learning may be particularly useful in scenarios where data is sensitive or subject to privacy constraints, or where it is impractical, inefficient, or expensive to centralize data. In the context of wireless communication, for example, federated learning may be used to improve performance by allowing an ANN to be trained on data collected from a wide range of devices and environments. For example, an ANN may be trained on data collected from a large number of wireless devices in a network, such as distributed wireless communication nodes, smartphones, or internet-of-things (IoT) devices, to improve the network's performance and efficiency. With federated learning, a user equipment (UE) or other device may receive a copy of all or part of a global or shared model and perform local training on the local model using locally available training data. The UE may provide updated information regarding the locally trained model to one or more other devices (such as a network entity or a server), where the updates from other-like devices (such as other UEs) may be aggregated and used to provide an update to the global or shared model. A federated learning process may be repeated iteratively until all or part of a model obtains a satisfactory level of performance. Federated learning may enable devices to protect the privacy and security of local data, while supporting collaboration regarding training and updating of all or part of a shared model.

In some implementations, one or more devices or services may support processes relating to an ML model's usage, maintenance, activation, reporting, or the like. In certain instances, all or part of a dataset or model may be shared across multiple devices to provide or otherwise augment or improve processing. In some examples, signaling mechanisms may be utilized at various nodes of wireless networks to signal the capabilities for performing specific functions related to ML models, support for specific ML models, capabilities for gathering, creating, and transmitting training data, or other ML related capabilities. ML models in wireless communication systems may, for example, be employed to support decisions or improve performance relating to wireless resource allocation or selection, wireless channel condition estimation, interference mitigation, beam management, positioning accuracy, energy savings, or modulation or coding schemes, etc. In some implementations, model deployment may occur jointly or separately at various network levels, such as a UE, a network entity such as a base station, or a disaggregated network entity such as a central unit (CU), a distributed unit (DU), a radio unit (RU), or the like.

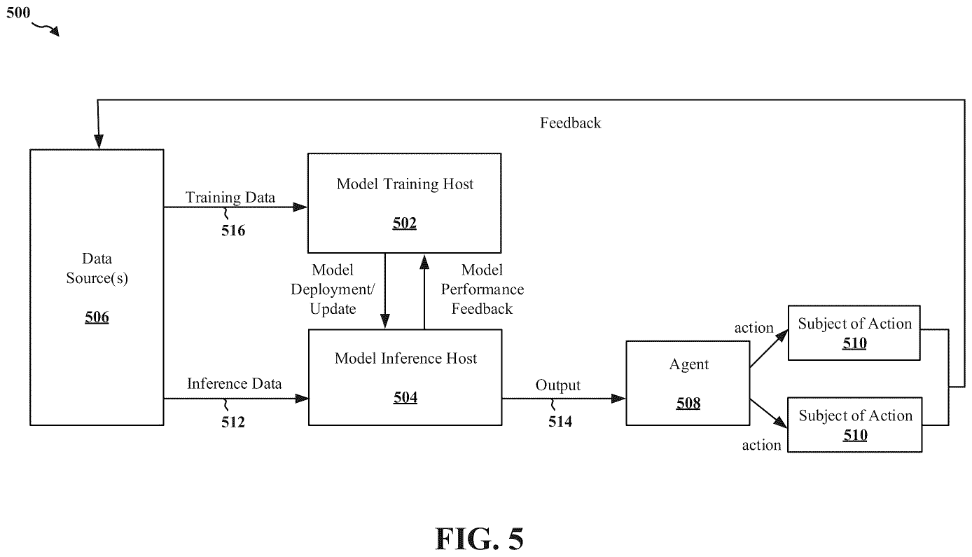

FIG. 5 is an illustrative block diagram of an example ML architecture 500 that may be used for wireless communications in any of the various implementations, processes, environments, networks, or use cases listed above. As illustrated, architecture 500 includes multiple logical entities, such as model training host 502, model inference host 504, data source(s) 506, and agent 508. Model inference host 504 is configured to run an ML model based on inference data 512 provided by data source(s) 506. Model inference host 504 may produce output 514, which may include a prediction or inference, such as a discrete or continuous value based on inference data 512, which may then be provided as input to the agent 508.

Agent 508 may represent an element or an entity of a wireless communication system including, for example, a radio access network (RAN), a wireless local area network, a device-to-device (D2D) communications system, etc. As an example, agent 508 may be a user equipment (such as UE 104, referring to FIG. 1, for example), a base station (such as base station 102, referring to FIG. 1, for example), or a disaggregated network entity (such as a CU 110, DU 130, or RU 140 in FIG. 1), an access point, a wireless station, a RAN intelligent controller (RIC) in a cloud-based RAN, among some examples. Additionally, agent 508 may also be a type of agent that depends on the type of tasks performed by model inference host 504, the type of inference data 512 provided to model inference host 504, or the type of output 514 produced by model inference host 504.

Agent 508 may perform one or more actions associated with receiving output 514 from model inference host 504, e.g., selection, use, and/or reporting regarding the inferences made for the different set of resources (e.g., traffic classification). Agent 508 may indicate the one or more actions performed to at least one subject of action 510. In some cases, agent 508 and the subject of action 510 are the same entity.

Data can be collected from data sources 506, and may be used as training data 516 for training an ML model, or as inference data 512 for feeding an ML model inference operation. Data sources 506 may collect data from various subject of action 510 entities (such as the UE or the network entity) and provide the collected data to a model training host 502 for ML model training. In some examples, if output 514 provided to agent 508 is inaccurate (or the accuracy is below an accuracy threshold), model training host 502 may provide feedback to model inference host 504 to modify or retrain the ML model used by model inference host 504, such as via an ML model deployment update.

Model training host 502 may be deployed at the same or a different entity than that in which model inference host 504 is deployed. For example, in order to offload model training processing, which can impact the performance of model inference host 504, model training host 502 may be deployed at a model server.

As computational models, including AI/ML models or functionalities (e.g., the AI/ML model including any of the aspects described in connection with the ANN 400 or the ML architecture 500) are increasingly utilized for various tasks in wireless communication, a UE may have multiple models (e.g., AI/ML models) trained for a variety of different tasks and use cases, such as traffic classification, interference prediction, beam prediction, CSI prediction, CSI compression, and/or positioning. However, UEs are constrained by limited computational, memory, and power resources, which are shared among these models (e.g., AI/ML models). As a result, UEs may not be able to operate all requested models or functionalities simultaneously. Example aspects presented herein provide methods and apparatus to configure UEs for scenarios where multiple tasks (e.g., AI/ML tasks) are scheduled to be performed despite the limitations in memory, compute, and other resources.

AI/ML models (e.g., the AI/ML model including any of the aspects described in connection with the ANN 400 or the ML architecture 500) can be adapted for use in various wireless communication scenarios due to their ability to provide significant performance enhancements. These models can leverage vast amounts of historical data to improve performance compared to various baselines. For example, AI/ML models can handle the high-dimensional features inherent in wireless environments, such as signal strength, beamforming patterns, and interference levels. Additionally, AI/ML models can capture the nonlinearities and dynamic conditions of wireless networks that analytical models often fail to comprehend. This capability leads to improved predictions of network behavior and more efficient allocation of radio resources.

AI/ML models can provide remarkable success in numerous wireless use cases. These include traffic classification, CSI prediction and compression, interference prediction, beam prediction, positioning and sensing, scheduling and resource selection, and reference signal design and optimization, among others. For example, the use cases of AI/ML models (e.g., the AI/ML model including any of the aspects described in connection with the ANN 400 or the ML architecture 500) may include enhancements in traffic management (e.g., with improved traffic classification), CSI feedback, beam management, and/or positioning accuracy. For CSI feedback enhancement, this may involve spatial-frequency domain CSI compression using AI/ML models deployed on both sides of the communication link, and time-domain CSI prediction utilizing models on the UE side. For beam management, use cases of AI/ML models may include spatial-domain downlink beam prediction for a first set of beams (e.g., Set A) based on measurement results from a second set of beams (e.g., Set B), and temporal downlink beam prediction for Set A beams based on the historical measurement results of Set B beams. For positioning accuracy enhancement, use cases of AI/ML models include direct AI/ML-based positioning and AI/ML-assisted positioning, as an example.

The adoption of AI/ML models (e.g., the AI/ML model including any of the aspects described in connection with the ANN 400 or the ML architecture 500) may use AI/ML model terminology and descriptions to identify common and specific characteristics for framework investigation. This includes characterizing the defining stages of AI/ML-related algorithms and associated complexities, identifying various levels of collaboration between the UE and network relevant to the selected use cases, and characterizing the lifecycle management of AI/ML models, among others.

In wireless communication, AI/ML training may be decentralized to enhance data privacy and improve model accuracy. Various approaches may be used to implement decentralized AI/ML training. In some aspects, federated learning (FL) or federated training, which is a machine learning technique that trains an AI/ML model across multiple decentralized edge nodes, such as different UEs and base stations (e.g., one or more components of gNBs). Each edge node may perform local model training using local data samples. The federated learning or federated training techniques may perform multiple model exchange interactions without the exchange of local data samples. In some aspects, AI/ML model transfer may be used, which involves the delivery of an AI/ML model via an over-the-air interface. An AI/ML model transfer may involve transferring parameters of a model structure that is already known at the receiving end or delivering a new model with its parameters. The delivery may include either a full model and/or a partial model. Example aspects presented herein provide methods for apparatus to enable physical layer processing to enable efficient federated AI/ML learning. Some example aspects provide a lattice-based quantization and coding method for federated machine learning training in coherent communication schemes, which enhances over-the-air (OTA) aggregation of model parameters by employing structured lattice codes to minimize quantization error and improve error correction. This approach allows UE to quantize model gradients to lattice points and aggregate them over the air without exchanging local data, thereby improving privacy and training efficiency. The method includes the use of lattice codes for quantization and error correction, scaling values for power constraints, dithering vectors to produce uniform quantization error, and a centralized unit for parameter aggregation.

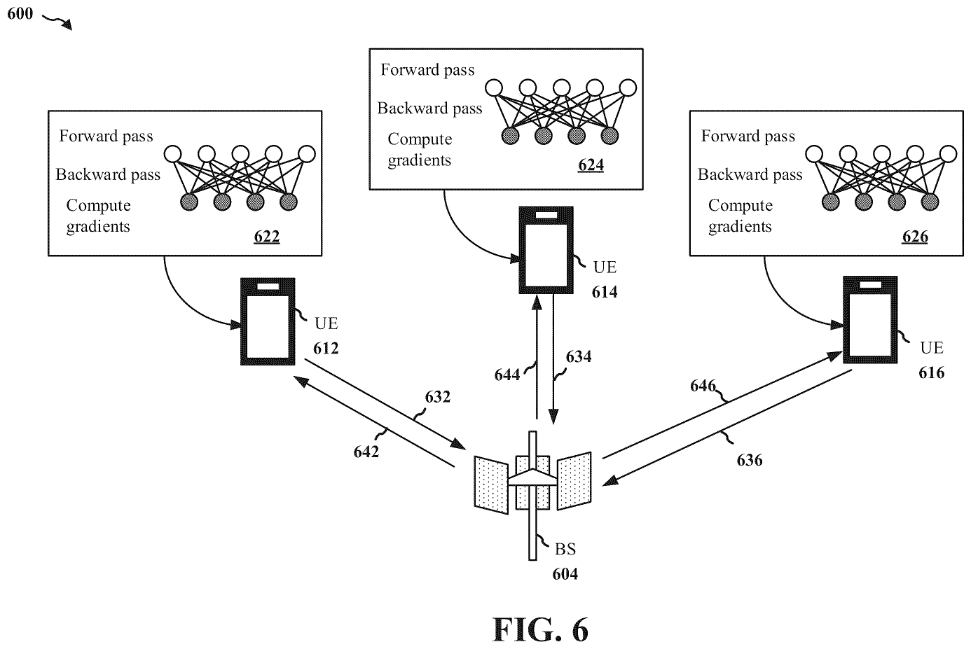

In some examples, the distributed edge machine learning federated learning process involves several steps. FIG. 6 is a diagram 600 illustrating an example of federated AI training, e.g., for an AI/ML model. As shown in FIG. 6, in the first step of a federated learning process, each UE (e.g., UE 612, 614, 616) may process its own local data in the form of mini-batches, and local data is not shared amongst UEs, thereby assuring privacy. For example, UE 612 may perform a forward pass, a backward pass, and compute gradients based on its local data at 622. Similarly, UE 614 may perform these operations using its local data at 624, and UE 616 may perform these operations using its local data at 626. In the second step, each UE (e.g., UE 612, 614, 616) may update its AI model based on its respective mini-batch. In the third step, the updated model parameters on each UE may be sent (e.g., via 632, 634, 636) to a centralized unit at the base station 604, where the model parameters may be averaged, benefiting from processing gain. In some aspects, each UE (e.g., UE 612, 614, 616) may send the updated model parameters in form of the updated weights of its AI model (or AI/ML model). In some examples (e.g., when the UEs were initialized with the same weights on its AI model), each UE (e.g., UE 612, 614, 616) may send the updated model parameters in form of a gradient vector for the weights of its AI model (or AI/ML model). For example, the gradient vector may include a set of gradients that reflect the difference between the updated weights and the previous weights. In the fourth step, the averaged model parameters may be subsequently sent back (e.g., via 642, 644, 646) to the various UEs (e.g., UE 612, 614, 616). The UEs update their respective models with the received parameters. These steps are repeated until convergence is attained (e.g., until the AI model's performance stabilizes). For example, each UE may recalculate its model parameters (e.g., weights or gradient vector) based on the updated model parameters (e.g., weights or gradient vector), determine further updates using local data, provide information about the determined update to the network, and receive a further update from the network based on a combination of information from multiple UEs until the base station (e.g., base station 604) determines that the learning process can be terminated (e.g., the convergence is achieved). Although the example is illustrated for a base station that is a central node for the federated learning, in other aspects, another network node may determine the updated model parameters and send them to the UEs, e.g., via a base station.

In some examples, physical layer techniques may be used to enable efficient usage of resources by OTA summation. For example, analog signals may be used to represent the model weights. The base station receive antenna may receive the summation of these signals from the UEs and, as a result, the reception inherently achieves an OTA aggregation in the form of summation or averaging. This scheme allows for efficient communication of the model weights or gradients by enabling all UEs to simultaneously share the air resources. In some examples, pre-equalization is used to prevent the model weights or gradients from being scaled by the channel response.

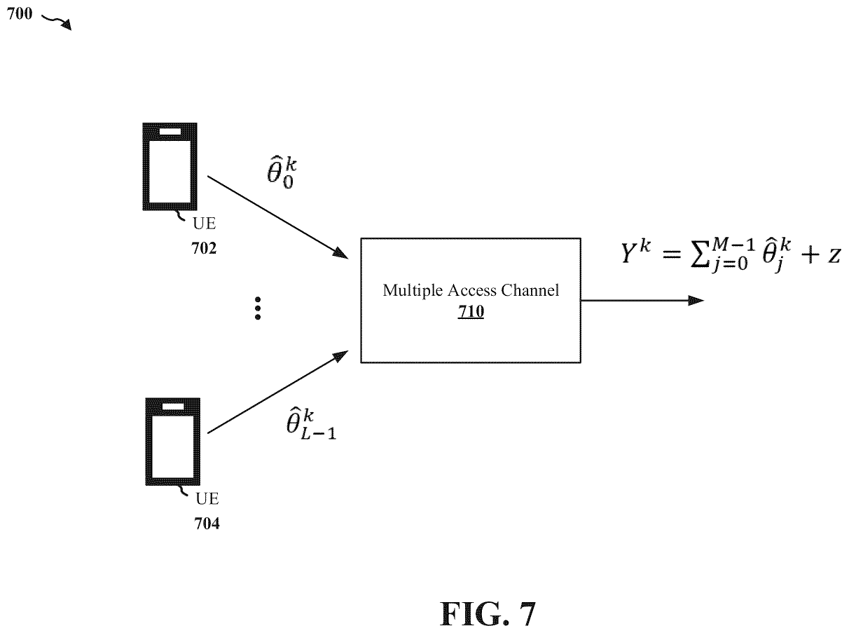

In some examples, federated AI training may take advantage of OTA aggregation to reduce communication overhead and improve spectrum efficiency. FIG. 7 is a diagram 700 illustrating an example of OTA aggregation for federated AI training. As shown in FIG. 7, in an OTA aggregation, each UE (e.g., UE 702, 704) may send the gradient of the model weights

$$( e . g . , {\hat{θ}}_{0}^{k} , … , {\hat{θ}}_{L - 1}^{k} )$$

to the network's parameter server (e.g., 710), which aggregates these gradients using a′ function such as summation to obtain an aggregated result (e.g., Y^{k}). Since wireless signals naturally combine over the uplink, it is advantageous for each user (e.g., UE 702, 704) to transmit the gradient of each model parameter simultaneously on the uplink. In some examples, this may result in the summation of the gradients being received at the base station. To ensure that the gradients

$$( e . g . , {\hat{θ}}_{0}^{k} , … , {\hat{θ}}_{L - 1}^{k} )$$

are correctly combined at the base station, several factors, such as power control, fading compensation, and phase correction may be properly addressed.

In some examples, lattice-based quantization and coding may be used in the federated learning process. In coding theory, a lattice is a structured, regular arrangement of points in an n-dimensional space. These points may be generated by linear combinations of a set of basis vectors with integer coefficients.

Lattices can be used in various applications, including quantization, error correction, and modulation. For quantization, lattice quantizers may be used for the combined quantization of multiple (K) real values to the nearest point in a K-dimensional lattice, minimizing the average quantization error, usually in the second moment sense. A lattice quantizer can achieve reduced quantization error compared to the commonly used per-element (e.g., cartesian) quantization. For error correction, lattice codes may be used to correct errors in transmitted data by transmitting a lattice point and mapping the received signal, which includes added channel noise, to the nearest lattice point. For modulation, lattice-based modulation schemes, such as lattice constellations, may be used to efficiently transmit data over communication channels.

A lattice Λ of dimension K is a subgroup of [symbol] ^{K} that is closed under reflection and real addition. The lattice Λ may be spanned by a generating matrix [symbol] ∈ [symbol] ^{K×K}, composed of real-valued elements, multiplied by a vector b of integer-valued elements. That is:

Λ={p= [symbol] b|b∈ [symbol] ^{K}} (1)
where p∈ [symbol] ^{K} is a lattice point, and the summation of lattice points: Σᵢpᵢ=Σᵢ [symbol] bᵢ= [symbol] Σᵢbᵢ is also a lattice point (Σᵢ bᵢ ∈ [symbol] ^{K}).

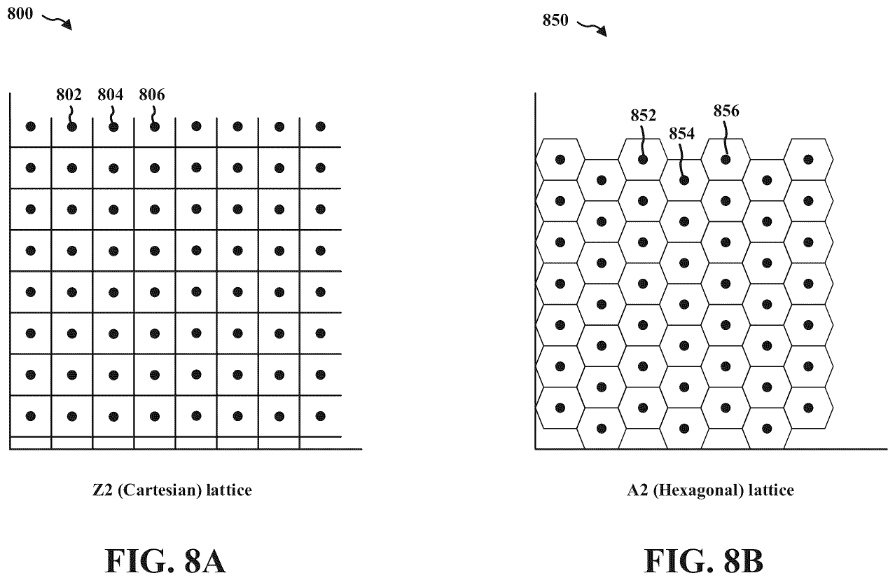

Given a lattice Λ, such as the lattice shown in FIG. 8A or FIG. 8B for K=2 or higher dimension Lattice (K>2), the nearest neighbor lattice quantizer Q_{Λ} for the lattice Λ may find the lattice point p that is closest to a given point x∈ [symbol] ^{K}, defined as:

$${Q}_{⋀} = arg {min}_{∈ p ∧} ‖ x - p ‖ \qquad ( 2 )$$

In some examples, a modulo lattice operation may be defined as an operator that finds the quantization error, defined as:

x mod Λ=x=Q_{Λ}(x) (3)

The Voronoi region of a lattice point p∈Λ is the set of all points in [symbol] ^{K} that are quantized to p. The basic Voronoi region v of the lattice Λ is the set of points that are mapped to the zero lattice point μ=0̅. The n-dimensional volume of the basic Voronoi region A is equal to:

VOL(v_{Λ})=|det(G)| (4)

where G is the generating matrix of the lattice.

FIG. 8A is a diagram 800 illustrating an example of two-dimensional cartesian lattice. In FIG. 8A, the lattice points (e.g., 802, 804, 806) form a cartesian lattice. The cartesian lattice has been normalized to a basic Voronoi region of V(v_{Λ})=1. FIG. 8A shows a Z2 lattice, which is the Cartesian 2D lattice with generating matrix

$${G}_{Z 2} = [ \begin{matrix}1 & 0 \\ 0 & 1\end{matrix} ] .$$

FIG. 8B is a diagram 850 illustrating an example of two-dimensional hexagonal lattice. In FIG. 8B, the lattice points (e.g., 852, 854, 856) form a hexagonal lattice. The hexagonal lattice has been normalized to a basic Voronoi region of V(v_{Λ})=1. FIG. 8B shows a A2 lattice, which is the hexagonal 2D lattice with a non-normalized generating matrix

$${G}_{A 2} = [ \begin{matrix}\sqrt{3} / 2 & 0 \\ 1 / 2 & 1\end{matrix} ] .$$

FIG. 8A and FIG. 8B show examples of two-dimensional lattices for illustrative purposes. In some examples, the lattice-based quantization and coding in some aspects of this disclosure may use a lattice with a dimension that is greater than 2 (e.g., K>>2).

In some examples, normalized second moment (NSM) may be used to evaluate the efficiency of a lattice quantizer. NSM is a scale-invariant metric that quantifies the mean square error between a source vector and its closest lattice point. The NSM may be used to determine the effectiveness of a lattice in approximating a given set of points.

For example, the NSM may be defined as:

$$N S M = \frac{1}{{nVOL ( {v}_{⋀} )}^{1 + 2 / K}} {\int }_{{v}_{⋀}} {‖ x ‖}^{2} dx \qquad ( 5 )$$

where K is the dimension of the lattice Λ, VOL(v_{Λ}) is the volume of the fundamental region v_{Λ} of the lattice, and ∥x∥ denotes the Euclidean norm of x.

In some examples, the NSM of the Z2 (square) Cartesian lattice (as shown in FIG. 8A) may have a Cartesian quantization noise variance 1/12=0.0833. In some examples, the A2 (hexagonal) lattice (as shown in FIG. 8B) may have the NSM of 0.0802, exhibiting a lower quantization noise variance for the same covered volume. In some examples, this gain may generally increase with the number of dimensions.

Example aspects presented herein provide methods and apparatus that add error correction code to the federated learning OTA aggregation process. In some examples, the error correction code may be designed such that the decoding of the OTA summation of distributed encoded gradient vectors from each edge node results in the summation of the original gradient vectors. That is:

dec(Σⱼenc(xⱼ))=Σ₁(xⱼ) (6)

where xⱼ is the K-dimensional gradient vector of the j-th user, and enc and dec represent the encoding and decoding functions, respectively. As Equation (6) involves the use of linear coding, lattice codes are therefore a good match for implementing the error correction code. Example aspects presented herein provide methods and apparatus that enable the use of lattices during the transmission and reception of model parameters for federated AI/ML training in OTA aggregation schemes.

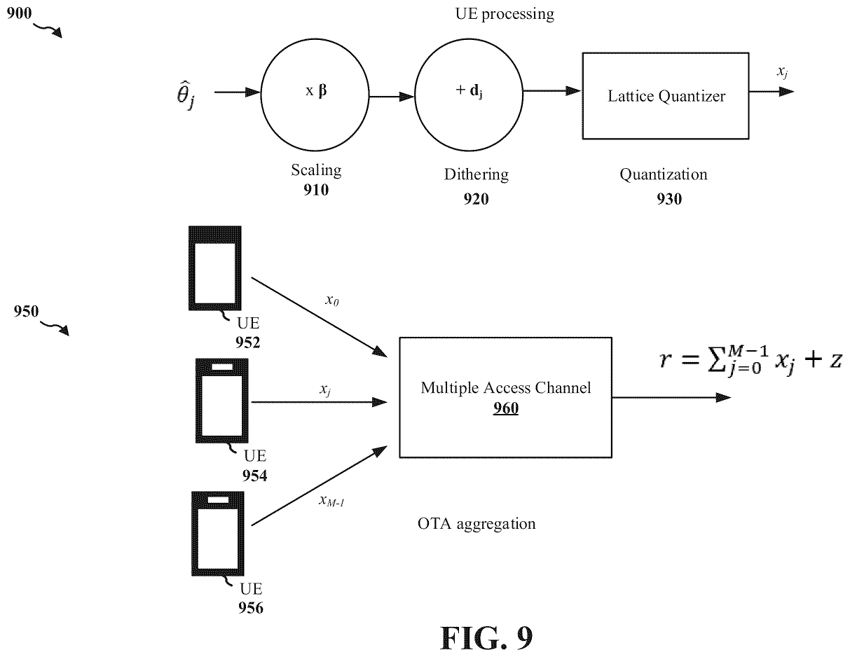

FIG. 9 shows diagrams illustrating an example of using lattice for quantization and coding of federated learning in accordance with various aspects of the present disclosure. As shown in FIG. 9, assuming there are M UEs (e.g., UE 952, 954, 956) taking part in the federated learning process, each UE, indexed by j (where j=0 to M−1), may send K gradients to the base station. The K-element vector of these gradient values is denoted as

$${\hat{θ}}_{j} = [ {\hat{θ}}_{j}^{0} , {\hat{θ}}_{j}^{1} , … , {\hat{θ}}_{j}^{K - 1} ] ∈ {ℝ}^{K} \qquad ( 7 )$$

As shown in diagram 900, each UE may first scales (e.g., at 910) its vector \hat{θ}ⱼ by a common scaling value β so that the transmission adheres to a given power constraint, such that

E{∥β\hat{θ}ⱼ∥²}≤P (8)

The scaling factor β may be common to all UEs (e.g., UE 952, 954, 956) and known at the base station (e.g., at 960).

The UE then may use a lattice Λ to quantize the scaled value (e.g., at 930) to the nearest lattice point. Before quantization, each UE may add (e.g., at 920) a dithering vector dⱼ to the scaled vector β\hat{θ}ⱼ. This dithering vector dⱼ may be draw uniformly over the basic Voronoi region of the lattice Λ, such that dⱼ∈v_{Λ}. The dithering process (e.g., at 920) ensures that the quantization error is uniformly distributed over the Voronoi region and independent of \hat{θ}ⱼ, thereby preventing bias in the quantized values.

These dithering vectors (e.g., dⱼ) may also be known at the base station to avoid introducing additional uncertainty. One approach to share the dithering vectors to use a common seed, shared between each UE and the base station, to generate the same sequence of dithering values at both entities.

In some examples, the lattice Λ used for quantization is a scaled version of a basic lattice Λ_{f}. For example, Λ_{f} can be a lattice that is normalized such that the volume of its basic Voronoi region satisfies VOL (v_{Λ}_{_{f}})=1. The scaled lattice is defined as:

Λ=αΛ_{f} (9)

where the scaling factor α should be common to all UEs and known at the base station.

In some examples, the lattice scaling factor α may affect both the quantization error and the system's robustness to noise, and may be selected based on the conditions on the quantization error and noise tolerance. A larger α may result in more dispersed lattice points, which increases quantization error, but also improves immunity to noise by decreasing the likelihood that the noise vector z will cause the received value to leave the Voronoi region of the correct lattice point. In some examples, the value of a may be chosen based on the lattice's NSM, and the variance

$$( e . g . , {σ}_{z}^{2} )$$

of the channel noise vector z.

In some examples, as shown in diagram 900 in FIG. 9, each UE (e.g., UE 952, 954, 956) may send the quantized value xⱼ=Q_{Λ}(β\hat{θ}ⱼ+dⱼ), where Q_{Λ}(⋅) is the lattice quantizer, β\hat{θ}ⱼ is the scaled gradient vector, and dⱼ is the dithering vector. The quantization error incurred in this process is qⱼ=(β\hat{θ}ⱼ+dⱼ)−xⱼ.

As shown in diagram 950, on the receiving side, assuming pre-equalization is applied by the UEs to avoid scaling of each UE's gradient, the base station (e.g., at 960) may receive the OTA summation of the M UE's transmissions after channel response and additive noise. The received signal is expressed as:

$$r = {\sum }_{j = 0}^{M - 1} {x}_{j} + z \qquad ( 10 )$$

where z∈ [symbol] ^{K} is a noise vector with K independent and identically distributed (IID) elements with variance

$${σ}_{z}^{2} .$$

Since a lattice is closed under real addition, the summation of the lattice points from all UEs,

$${\sum }_{j = 0}^{M - 1} {x}_{j} ,$$

is itself a lattice point.

Provided that the added noise z lies within the basic Voronoi region z∈v_{Λ} of the lattice (i.e., the noise does not cause the received signal to exit the Voronoi region of the correct lattice point), the receiver may accurately recover the summation of the lattice points using the lattice quantizer, such that

$${Q}_{⋀} ( r ) = {\sum }_{j = 0}^{M - 1} {x}_{j} ,$$

effectively eliminating the effect of the added noise z.

In some examples, the base station (e.g., at 960) may use the output of the lattice quantizer to estimate the OTA summation of the UEs' gradients, denoted as u, where the true summation is

$$u = {\sum }_{j = 0}^{M - 1} {\hat{θ}}_{j} .$$

The distortion in the base station's estimation (u) is defined as

$$D = \frac{1}{K} {Σ}_{k = 0}^{K - 1} E \{ {( {u}_{k} - {û}_{k} )}^{2} \} ,$$

where uₖ and ûₖ are the k-th elements of the vectors u and û, respectively. The base station may target to minimize this distortion to improve the accuracy of the aggregated model update.

In some aspects, while the scheme described may be applied in cases where the number of available channel uses (e.g., N) equals the number of transmitted gradients (e.g., K), in systems where additional channel uses are available (i.e., N>K), these extra channel uses may be utilized to reduce the distortion in the base station's estimation of the OTA summation of the UEs' gradients. For example, for the first K channel uses described previously, and assuming that the channel noise has been eliminated, the base station receives

$${Q}_{∧} ( r ) = {Σ}_{j = 0}^{M - 1} {x}_{j} = {Σ}_{j = 0}^{M - 1} β {\hat{θ}}_{j} + {Σ}_{j = 0}^{M - 1} {d}_{j} - {Σ}_{j = 0}^{M - 1} {q}_{j} .$$

Since β and the summation of dithering vectors

$${Σ}_{j = 0}^{M - 1} {d}_{j}$$

are known at the base station, the remaining uncertainty (hence the source of distortion) comes from the term

$${Σ}_{j = 0}^{M - 1} {q}_{j} ,$$

which is the summation of all quantization noises added by the UEs. These individual quantization errors qⱼ are known to the respective UEs.

In some examples, when K additional channel uses are available (i.e., N≥2K), each UE may transmit the quantization error qⱼ that was introduced during the lattice quantization of xⱼ. This may be performed in a manner similar to the transmission of the original gradients \hat{θ}ⱼ. Each UE may first scale qⱼ by a common scaling factor γ to meet a power constraint condition, such as

E{∥γqⱼ∥²}≤P (11)

where γ is common to all UEs and known at the base station. The UE then may add a dithering vector dⱼ′, generated based on a shared seed, and quantize the result to the lattice using

$${x}_{j}^{′} = {Q}_{∧} ( γ {q}_{j} + {d}_{j}^{′} ) .$$

In some examples, the transmission of qⱼ may introduces a new, smaller quantization error defined as

$${q}_{j}^{′} = ( γ {q}_{j} + {d}_{j}^{′} ) - {x}_{j}^{′} .$$

At the receiver side, the base station may use the lattice quantizer, as was done with xⱼ, to estimate the summation of all UEs' quantization errors

$${Σ}_{j = 0}^{M - 1} {q}_{j}$$

and reduce the total distortion in its estimation (u) of the true OTA summation

$$u = {Σ}_{j = 0}^{M - 1} {\hat{θ}}_{j} .$$

In the same manner, each additional group of K additional channel uses can be employed to further reduce the quantization noise introduced in the previous quantization steps. For simplicity, the description assumes that the ratio N/K is an integer, although the approach can be adapted for non-integer cases as well.

In some aspects, the distortion in the base station's estimation (u) of the OTA summation u is defined as:

$$D = \frac{1}{K} {Σ}_{k = 0}^{K - 1} E \{ {( {u}_{k} - {û}_{k} )}^{2} \} \qquad ( 12 )$$

where uₖ and ûₖ are the k-th elements of the actual and estimated summation vectors, respectively. For the case where the number of channel uses N equals the number of transmitted gradients K (i.e., N=K), the distortion of is given by

$$D = \frac{M {σ}_{s}^{2} {σ}_{z}^{2}}{P + {σ}_{z}^{2}} \qquad ( 13 )$$

where

$${σ}_{s}^{2}$$

represents the variance of the gradient values (assumed to be IID Gaussian), and

$${σ}_{z}^{2}$$

is the variance of the additive white Gaussian noise (AWGN).

In some examples, the optimal distortion in this case may be achieved using uncoded analog transmission, which has a distortion of:

$${D}_{opt} = M {σ}_{s}^{2} {σ}_{z}^{2} / ( MP + {σ}_{z}^{2} ) \qquad ( 14 )$$

This value is known as the Shannon distortion lower bound.

For scenarios where N>K, the analog scheme with repetition may use each additional group of K channel uses to retransmit the same K gradient vector \hat{θ}ⱼ. The distortion for the repetition scheme is given by:

$${D}_{REP} = M {σ}_{s}^{2} {σ}_{z}^{2} / ( \frac{N}{K} MP + {σ}_{z}^{2} ) \qquad ( 15 )$$

Although the proposed scheme does not reach the Shannon lower bound, it still provides a coding gain and supports a reliable and reproducible training process, even in the case where N=K. This reliability is attributed to the elimination of the AWGN term z at the base station in the proposed scheme, which is not the case for either the uncoded analog scheme or the repetition scheme, where the AWGN remains a source of distortion. As a result, in those schemes, the estimated value may vary with each realization of noise. In contrast, the proposed scheme ensures consistent estimation and offers a coding gain (e.g., at SNR levels greater than 12 dB with a coding rate of K/N=1/3).

In some aspects, to support the lattice-based quantization and coding for federated AI/ML OTA training, at the beginning of the ML/AI federated learning training process, each UE may exchange with the base station the information necessary to set up the use of lattices for quantization and coding during the training. This exchanged information may include a scaling value β, which is used for scaling (e.g., at 910) the gradients so that they comply with a power constraint P. In some examples, each UE may also be assigned a unique seed for dithering vector generation. This seed may be used to initialize a random generator that produces a dithering vector (e.g., dⱼ at 920) specific to each UE, which is also known to the base station to avoid additional uncertainty.

In some aspects, the exchanged information may further include the information of the basic lattice Λ_{f} to be used for quantization, as well as the number of lattice dimensions K, which also corresponds to the number of gradients that are quantized and transmitted together. In some examples, the exchanged information may include the lattice's generating matrix. In some examples, the exchanged information may include a lattice scaling value α may be specified for use during the quantization process. This value (α) might be selected based on an initial estimation of the signal-to-noise ratio (SNR) and other channel state indicators (CSI).

In some aspects, the exchanged information may include a coding rate K/N. For example, the base station may manage the coding rate based on available system resources to reduce parameter distortion, increase reliability through coding gain, or allocate the resources for other purposes, depending on the SNR and other CSI values.

In some aspects, the exchanged information may include the scaling value γ, which may be used for scaling the quantization errors in cases where N>K, ensuring those transmissions also comply with the power constraint P.

In some aspects, the base station may periodically estimate the channel parameters and update the UEs when lattice-related communication parameters need to be updated. For example, these updates may include updated lattice scaling values a and γ, which may be used during the next mini-batch or epoch training period. The updated values may be adjusted based on the updated SNR estimations and other channel state indicators (CSI). In some aspects, the updates may include updated coding rate K/N, which may be used during the following mini-batch or epoch training period. The updated coding rate may also depend on the updated SNR estimation and other CSI values.

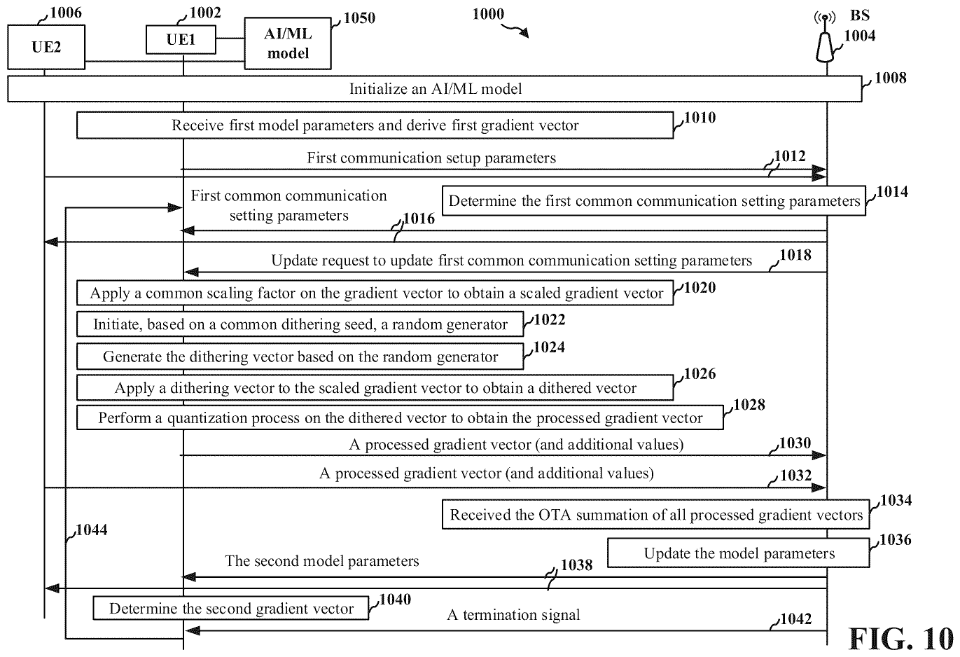

FIG. 10 is a call flow diagram 1000 illustrating a method of wireless communication in accordance with various aspects of this present disclosure. Various aspects are described in connection with multiple UEs, such as a first UE 1002 and a second UE 1006, and a base station 1004. The aspects may be performed by the first UE 1002, the second UE 1006, or the base station 1004 in aggregation and/or by one or more components of a base station 1004 (e.g., a CU 110, a DU 130, and/or an RU 140). A base station or one or more components of a base station, is an example of a network node or network entity that may be involved in federated learning, as described herein. In some examples, the first UE 1002 may include or be associated with an AI/ML model 1050. In some examples, the AI/ML model 1050 may be shared among the multiple UEs and the base station, such as the first UE 1002, the second UE 1006, and base station 1004. For example, the AI/ML model 1050 may include any of the aspects described in connection with the ANN 400 or the ML architecture 500. In some examples, the AI/ML model 1050 may be used to provide computing capabilities for wireless communications between base station 1004 and the UE (e.g., the first UE 1002). For example, the AI/ML model 1050 may be configured with weights and biases to perform tasks such as beam prediction, CSI prediction, CSI compression/decompression, interference prediction, positioning, sensing, scheduling and resource selection, and/or reference signal design and optimization, among other examples. In some examples, the AI/ML model 1050 may also be used for other tasks, which may or may not involve communication between the base station 1004 and the UE (e.g., the first UE 1002).

As shown in FIG. 10, at 1008, the AI/ML model 1050 may be initialized on the first UE 1002, the second UE 1006 and base station 1004. For example, the initialization of the AI/ML model 1050 may include initializing identical AI/ML model parameters for the AI/ML model 1050 on the first UE 1002, the second UE 1006, and base station 1004. For example, the AI/ML model parameters may include the gradient vectors (e.g., \hat{θ}ⱼ) for AI/ML model 1050.

For example, at 1010, the first UE 1002 may receive first model parameters (e.g., the initial model parameters of AI/ML model 1050 initialized at 1008) and derive first gradient vector through AI/ML training. For example, the first model parameters may include initial weights for AI/ML model 1050, and the first gradient vector may be \hat{θ}ⱼ based on the initial model parameters of AI/ML model 1050. In some aspects, the first gradient vector may include a set of gradients, and each gradient may represent the difference between a new weight and the corresponding initial weight of the AI/ML model 1050.

Then, at 1012, the first UE 1002 may transmit the first communication setup parameters based on the first gradient vector to base station 1004. For example, the first communication setup parameters may include the maximum value (or maximum absolute value) of the elements of the first gradient vector (e.g., \hat{θ}j), the variance of the elements of the first gradient vector (e.g., \hat{θ}ⱼ). In some examples, the first communication setup parameters may further include channel statistics (e.g., signal-to-noise ratio (SNR) of the channel) of the channel between the first UE 1002 and base station 1004.

In some examples, the second UE 1006 may transmit its first communication setup parameters based on the gradient vector on the second UE 1006 to base station 1004. For example, the first communication setup parameters from the second UE 1006 may include the maximum value (or maximum absolute value) of the elements of the gradient vector (e.g., \hat{θ}ⱼ) on the second UE 1006, the variance of the elements of the gradient vector (e.g., \hat{θ}ⱼ) on the second UE 1006, or the channel statistics (e.g., SNR of the channel) of the channel between the second UE 1006 and base station 1004.

At 1014, the base station 1004 may use the collected communication setup parameters from all UEs (e.g., the first UE 1002 and the second UE 1006), along with additional information such as the number of available channel uses, to determine the first set of common communication settings parameters. For example, the communication setting parameters may include parameters related to a lattice-based quantization and coding scheme for communication between the UE and base stations. For example, the communication setting parameters may include a common scaling factor (e.g., β at 910), a common dithering seed (e.g., the seed to generate dⱼ at 920), and a common scaled lattice structure for the lattice-based quantization and coding scheme (e.g., at 930).

At 1016, the base station 1004 may send the first common communication setting parameters to all UEs, such as the first UE 1002 and the second UE 1006. The first common communication setting parameters may be applied to each UE of these UEs (e.g., the first UE 1002 and the second UE 1006).

Upon receiving the first common communication setting parameters, each UE (e.g., the first UE 1002, the second UE 1006) may process its gradient vector (e.g., θⱼ) for transmission. If additional channel uses are available (i.e., N>K), the UE may derive additional values related to the gradient vector to further reduce distortion and include these in the transmission.

In some examples, the base station 1004 may, at 1018, transmit to the first UE 1002 an update request to update all or a subset of the first common communication setting parameters. In some examples, the base station 1004 may periodically transmit an update request to the first UE 1002 to update all or a subset of the first common communication setting parameters.

In some examples, the update request may be based on one or more of: the change to an initial estimation of an SNR associated with the base station 1004 and the first UE 1002, or the change to a channel state indicator. In some aspects, the update request may include one or more of: the update to the common lattice scaling factor (e.g., β at 910), a second update to the error scaling factor, or a third update to the coding rate (e.g., K/N).

Steps 1020 through 1030 illustrate an example in which the first UE 1002 uses the first common communication setting parameters to process its gradient vector (e.g., \hat{θ}ⱼ) and transmits the processed gradient vector to the base station 1004.

At 1020, the first UE 1002 may apply a common scaling factor (e.g., β at 910) on the gradient vector (e.g., \hat{θ}ⱼ) based on a power constraint of the first UE 1002 to obtain a scaled gradient vector. For example, referring to FIG. 9, the first scaling factor may be β at 910. The power constraint may be expressed as Equation (8).

At 1022, the UE 1002 may initiate a random generator based on the common dithering seed, and, at 1024, generate the dithering vector (e.g., d, at 920) based on the random generator.

At 1026, the first UE 1002 may apply the dithering vector to the scaled gradient vector to obtain a dithered vector. For example, referring to FIG. 9, the first UE 1002 may apply a dithering vector (e.g., at 920) to the scaled gradient vector to obtain a dithered vector.

For example, the common scaling factor at 1020, the common dithering seed for generating the dithering vector at 1022 may be included in the first common communication setting parameters at 1016.

At 1028, the first UE 1002 may perform a quantization process on the dithered vector to obtain the processed gradient vector. For example, referring to FIG. 9, the first UE 1002 may perform a quantization process (e.g., at 930) on the dithered vector to obtain the processed gradient vector (e.g., xⱼ). For example, the first UE 1002 may use a lattice Λ to quantize the dithered value to the nearest lattice point.

At 1030, the first UE 1002 may transmit, to base station 1004, the processed gradient vector. For example, the first UE 1002 may obtain the processed gradient vector by applying the scaling (e.g., at 1020), dithering (e.g., at 1026) and lattice-based quantization (e.g., at 1028) processes on the first gradient vector.

In some examples, if the available channel uses between the first UE 1002 and the base station 1004 is greater than the number of gradients in the gradient vector, the first UE 1002 may transmit, to the base station 1004, additional values related to the processed gradient vector at 1030. In some examples, the additional values may be related to the gradient vector to further reduce distortion.

In addition to the first UE 1002, the base station 1004 may receive the processed gradient vector from other UEs. For example, the base station 1004 may, at 1032, receive the processed gradient vector from the second UE 1006. Similar to the first UE 1002, the second UE 1006 may obtain the processed gradient vector by applying a scaling (e.g., at 910), dithering (e.g., at 920) and lattice-based quantization (e.g., at 930) processes on the first gradient vector on the second UE 1006.

At 1034, the base station 1004 may receive the OTA summation of all processed gradient vectors, along with OTA summation of any additional values.

At 1036, the base station 1004 may update the model parameter of the AI/ML model 1050 based on the OTA summation of the processed gradient vectors, along with OTA summation of any additional values from multiple UEs (e.g., the first UE 1002, the second UE 1006). The updated model parameters may be referred to as the second model parameters.

At 1038, the base station 1004 may transmit the updated model parameter (e.g., second model parameters), either as updated weights or as an averaged gradient vector, to the multiple UEs (e.g., the first UE 1002, the second UE 1006).

Each UE (e.g., the first UE 1002), upon receiving the second model parameters at 1038, may, at 1040, derive a second gradient vector using AI/ML training and repeat the process (e.g., at 1044) beginning from step 1016, reusing the initial common communication settings parameters (e.g., the first common communication setting parameters) received in the first iteration. In some examples, the steps involved in updating the model parameters of the AI/ML model 1050 may be collectively referred to as the model update process. For example, in FIG. 10, the model update process for the first UE 1002 may include at least steps 1030 through 1040.

In some examples, the model update process may be repeated performed based on the first common communication setting parameters (at 1016) until a condition is met. For example, the condition may include the convergence is attained (e.g., the performance of the AI/ML model 1050 stabilizes) or a signal to terminate the model update process is received.

In some examples, the base station 1004 may, at 1042, send to first UE 1002 a termination signal for the model update process. Upon receiving the termination signal, the first UE 1002 may terminate the model update process.

In some examples, steps 1012 through 1016 may be periodically repeated. That is, the UE (e.g., the first UE 1002) may transmit the communication setup parameters and receive updated communication settings parameters periodically. In some examples, the updated communication settings parameters (at 1016) may be a subset of the initial communication setting parameters and may be used to update values such as lattice scaling and code rate when the number of available channel uses changes.

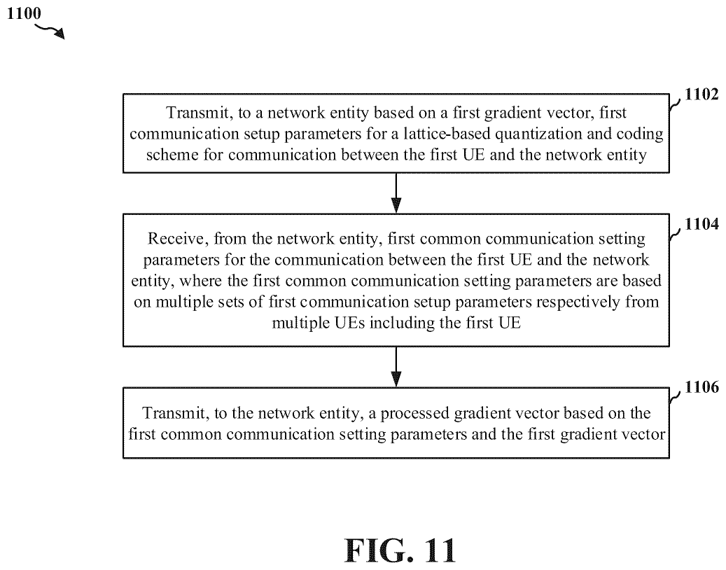

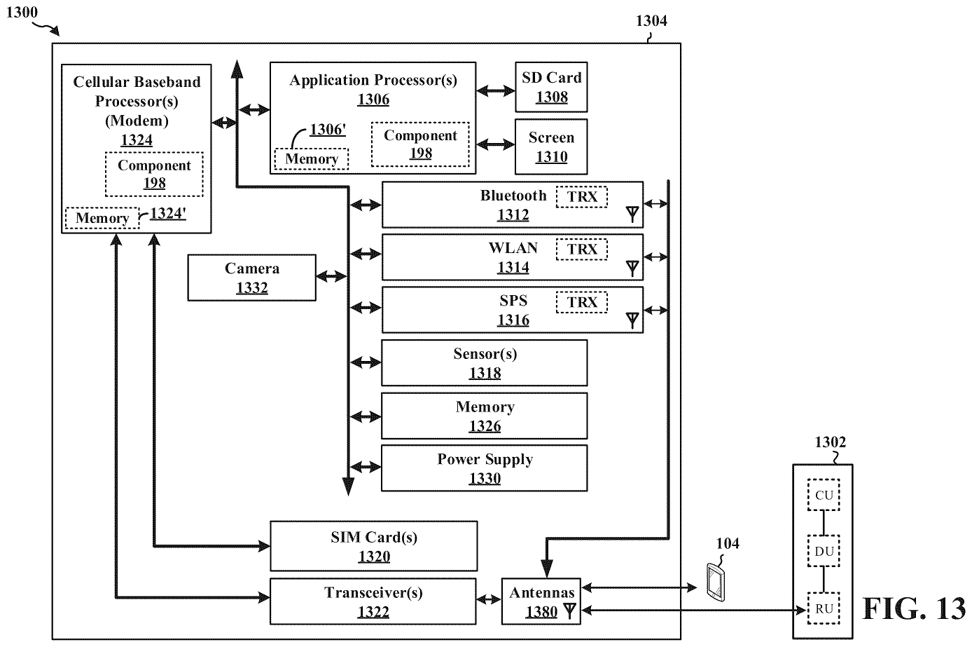

FIG. 11 is a flowchart 1100 illustrating methods of wireless communication at a first UE in accordance with various aspects of the present disclosure. The method may be performed by the first UE in collaboration with a network entity. The network entity may be a base station, or a component of a base station, in the access network of FIG. 1 or a core network component (e.g., base station 102, 310, 1004; or the network entity 1302 in the hardware implementation of FIG. 13). The first UE may be the UE 104, 350, 612, 614, 616, 952, 954, 956, 1002, or the apparatus 1304 in the hardware implementation of FIG. 13. By introducing lattice-based quantization and coding into federated AI/ML OTA training in a coherent wireless communication scheme, the methods reduce the quantization error (distortion) during transmission of model parameters, resulting in more accurate aggregation at the base station and improved training convergence. Additionally, by dynamically adapting communication setting parameters (e.g., lattice scaling, code rates) based on channel conditions, the methods provide robustness and flexibility in varying wireless conditions, thereby improving the performance of wireless communication.

As shown in FIG. 11, at 1102, the first UE may transmit, to a network entity based on a first gradient vector, first communication setup parameters for a lattice-based quantization and coding scheme for communication between the first UE and the network entity. FIG. 6, FIG. 7, FIG. 9, and FIG. 10 illustrate various aspects of the steps in connection with flowchart 1100. For example, referring to FIG. 10, the first UE 1002 may transmit, at 1012, to a network entity (e.g., base station 1004) based on a first gradient vector, first communication setup parameters for a lattice-based quantization and coding scheme for communication between the first UE 1002 and the network entity (e.g., base station 1004). In some aspects, 1102 may be performed by the quantization and coding component 198.

At 1104, the first UE may receive, from the network entity, first common communication setting parameters for the communication between the first UE and the network entity. The first common communication setting parameters may be based on multiple sets of first communication setup parameters respectively from multiple UEs including the first UE. For example, referring to FIG. 10, the first UE 1002 may, at 1016, receive from the network entity (e.g., base station 1004) first common communication setting parameters for the communication between the first UE 1002 and the network entity (e.g., base station 1004). The first common communication setting parameters may be based on multiple sets of first communication setup parameters respectively from multiple UEs (e.g., the first UE 1002 and the second UE 1006) including the first UE 1002. In some aspects, 1104 may be performed by the quantization and coding component 198.

At 1106, the first UE may transmit, to the network entity, a processed gradient vector based on the first common communication setting parameters and the first gradient vector. For example, referring to FIG. 10, the first UE 1002 may, at 1030, transmit, to the network entity (e.g., base station 1004), a processed gradient vector based on the first common communication setting parameters and the first gradient vector. In some aspects, 1106 may be performed by the quantization and coding component 198.

In some aspects, the first gradient vector and the processed gradient vector may be associated with an AI/ML model, and the first UE may receive, from the network entity, first model parameters for the AI/ML model. The first gradient vector may be based on the first model parameters. For example, referring to FIG. 10, the first gradient vector (e.g., at 1010) and the processed gradient vector (e.g., at 1030) may be associated with an AI/ML model 1050, and the first UE 1002 may, at 1010, receive from the network entity (e.g., base station 1004) first model parameters for the AI/ML model 1050. The first gradient vector may be based on the first model parameters.

In some aspects, the first UE may receive, from the network entity, second model parameters for the AI/ML model. The second model parameters may be based on an aggregation of multiple processed gradient vectors respectively from the multiple UEs. The first UE may further determine a second gradient vector based on the second model parameters. For example, referring to FIG. 10, the first UE 1002 may, at 1038, receive from the network entity (e.g., base station 1004) second model parameters for the AI/ML model 1050. The second model parameters may be based on an aggregation of multiple processed gradient vectors (e.g., the OTA summation of all processed gradient vectors at 1034) respectively from the multiple UEs (e.g., the first UE 1002 and the second UE 1006). The first UE 1002 may, at 1040, further determine a second gradient vector based on the second model parameters.

In some aspects, the first UE may repeat a model update process for the AI/ML model based on first common communication setting parameters and a current gradient vector. In some aspects, the model update process may include: transmitting, to the network entity, an updated gradient vector based on the first common communication setting parameters and the current gradient vector; receiving, from the network entity, an update to current model parameters for the AI/ML model, where the update to the current model parameters is based on an aggregation of multiple updated gradient vectors respectively from the multiple UEs; and updating the current gradient vector based on the update to the current model parameters. For example, referring to FIG. 10, the first UE 1002 may repeat (e.g., via 1044) a model update process for the AI/ML model 1050 based on first common communication setting parameters (e.g., at 1012) and a current gradient vector. In some aspects, the model update process may include: transmitting, to the network entity, an updated gradient vector (e.g., processed gradient vector at 1030) based on the first common communication setting parameters (e.g., at 1016) and the current gradient vector; receiving (e.g., at 1038), from the network entity (e.g., base station 1004), an update to current model parameters for the AI/ML model (e.g., the second model parameters at 1038), where the update to the current model parameters is based on an aggregation of multiple updated gradient vectors respectively from the multiple UEs; and updating (e.g., at 1040) the current gradient vector based on the update to the current model parameters.

In some aspects, the first UE may receive, from the network entity, a termination signal for the model update process; and terminate the model update process based on the termination signal. For example, referring to FIG. 10, the first UE 1002 may, at 1042, receive, from the network entity (e.g., base station 1004), a termination signal for the model update process; and terminate the model update process based on the termination signal.

In some aspects, the processed gradient vector may include a first number of gradients for the AI/ML model, and the available channel uses between the first UE and the network entity may be a second number greater than the first number. The first UE may transmit, to the network entity, additional values related to the processed gradient vector. For example, referring to FIG. 10, if the available channel uses between the first UE 1002 and the network entity (e.g., base station 1004) is greater than the first number, the first UE 1002 may, at 1030, transmit, to the network entity (e.g., base station 1004), additional values related to the processed gradient vector.

In some aspects, the first communication setup parameters may include model information and channel information. The model information may include one or more of: the maximum absolute value among gradients in the first gradient vector, or the gradient variance of the gradients in the first gradient vector. The channel information may include a noise variance for an additive AWGN associated with the channel between the first UE and the network entity. For example, referring to FIG. 10, the first communication setup parameters (e.g., at 1012) may include model information and channel information. The model information may include one or more of: the maximum absolute value among gradients in the first gradient vector (e.g., \hat{θ}ⱼ), or the gradient variance of the gradients in the first gradient vector (e.g., \hat{θ}ⱼ). The channel information may include a noise variance for an additive AWGN associated with the channel between the first UE 1002 and the network entity (e.g., base station 1004).

In some aspects, the first common communication setting parameters may include a common scaling factor, a common dithering seed, and a common scaled lattice structure for the lattice-based quantization and coding scheme, and the first common communication setting parameters may be applied to each UE of the multiple UEs. For example, referring to FIG. 10, the first common communication setting parameters may include a common scaling factor (e.g., β at 910), a common dithering seed (e.g., the seed to generate d, at 920), and a common scaled lattice structure for the lattice-based quantization and coding scheme, and the first common communication setting parameters may be applied to each UE of the multiple UEs (e.g., the first UE 1002, the second UE 1006).

In some aspects, the first common communication setting parameters may include a lattice scaling factor, and the lattice scaling factor may be based on one or more of: an initial estimation of a signal-to-noise ratio (SNR) associated with the first UE and the network entity, or a channel state indicator. For example, referring to FIG. 10, the first common communication setting parameters (e.g., at 1016) may include a lattice scaling factor (e.g., α in Equation (9)), and the lattice scaling factor (e.g., α in Equation (9)) may be based on one or more of: an initial estimation of the SNR associated with the first UE 1002 and the network entity (e.g., base station 1004), or a channel state indicator.

In some aspects, the first UE may apply the common scaling factor on the first gradient vector based on a power constraint of the first UE to obtain a scaled gradient vector; apply a dithering vector to the scaled gradient vector to obtain a dithered vector, where the dithering vector is based on the common dithering seed; and perform, based on the common scaled lattice structure, a quantization process on the dithered vector to obtain the processed gradient vector. For example, referring to FIG. 9 and FIG. 10, the first UE 1002 may, at 1020, apply the common scaling factor (e.g., β at 910) on the first gradient vector based on a power constraint of the first UE to obtain a scaled gradient vector, apply, at 1026, a dithering vector to the scaled gradient vector to obtain a dithered vector, where the dithering vector is based on the common dithering seed, and, at 1028, perform, based on the common scaled lattice structure, a quantization process on the dithered vector to obtain the processed gradient vector.

In some aspects, the first UE may initiate, based on the common dithering seed, a random generator; and generate the dithering vector based on the random generator. For example, referring to FIG. 10, the first UE 1002 may, at 1022, initiate, based on the common dithering seed, a random generator; and, at 1024, generate the dithering vector based on the random generator.

In some aspects, the first common communication setting parameters may further include one or more of: an error scaling factor for scaling quantization errors based on a power constraint of the first UE, a basic lattice structure having dimensions of a first number for the lattice-based quantization and coding scheme, a lattice scaling factor associated with the basic lattice structure and the common scaled lattice structure, or a coding rate based on the first number and a number of channel uses associated with the first UE. For example, referring to FIG. 10, the first common communication setting parameters (e.g., at 1016) may further include one or more of: an error scaling factor for scaling quantization errors based on a power constraint of the first UE, a basic lattice structure (e.g., Λ_{f} in Equation (9)) having dimensions of a first number for the lattice-based quantization and coding scheme, a lattice scaling factor (e.g., α in Equation (9)) associated with the basic lattice structure and the common scaled lattice structure, or a coding rate (e.g., K/N) based on the first number (e.g., K) and a number of channel uses (e.g., N) associated with the first UE.

In some aspects, the first UE may receive, from the network entity, an update request to update all or a subset of the first common communication setting parameters periodically. For example, referring to FIG. 10, the first UE 1002 may, at 1018, receive, from the network entity (e.g., base station 1004), an update request to update all or a subset of the first common communication setting parameters periodically.

In some aspects, the update request may be based on one or more of: a first change to an initial estimation of an SNR associated with the network entity and the first UE, or a second change to a channel state indicator.

In some aspects, the update request may include one or more of: a first update to the common lattice scaling factor, a second update to the error scaling factor, or a third update to the coding rate (e.g., K/N).

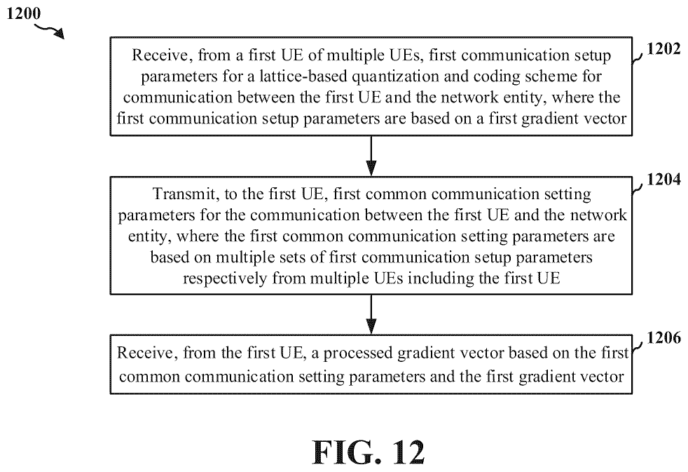

FIG. 12 is a flowchart 1200 illustrating methods of wireless communication at a network entity in accordance with various aspects of the present disclosure. The method may be performed by a network entity in collaboration with a first UE. The network entity may be a base station, or a component of a base station, in the access network of FIG. 1 or a core network component (e.g., base station 102, 310, 1004; or the network entity 1302 in the hardware implementation of FIG. 13). The first UE may be the UE 104, 350, 612, 614, 616, 952, 954, 956, 1002, or the apparatus 1304 in the hardware implementation of FIG. 13. By introducing lattice-based quantization and coding into federated AI/ML OTA training in a coherent wireless communication scheme, the methods reduce the quantization error (distortion) during transmission of model parameters, resulting in more accurate aggregation at the base station and improved training convergence. Additionally, by dynamically adapting communication setting parameters (e.g., lattice scaling, code rates) based on channel conditions, the methods provide robustness and flexibility in varying wireless conditions, thereby improving the performance of wireless communication.

As shown in FIG. 12, at 1202, the network entity may receive, from a first UE of multiple UEs, first communication setup parameters for a lattice-based quantization and coding scheme for communication between the first UE and the network entity. The first communication setup parameters are based on a first gradient vector. FIG. 6, FIG. 7, FIG. 9, and FIG. 10 illustrate various aspects of the steps in connection with flowchart 1200. For example, referring to FIG. 10, the network entity (e.g., base station 1004) may, at 1012, receive, from a first UE 1002 of multiple UEs (e.g., the first UE 1002 and the second UE 1006), first communication setup parameters for a lattice-based quantization and coding scheme for communication between the first UE 1002 and the network entity (e.g., base station 1004). The first communication setup parameters are based on a first gradient vector. In some aspects, 1202 may be performed by the quantization and coding component 199.

At 1204, the network entity may transmit, to the first UE, first common communication setting parameters for the communication between the first UE and the network entity. The first common communication setting parameters may be based on multiple sets of first communication setup parameters respectively from multiple UEs including the first UE. For example, referring to FIG. 10, the network entity (e.g., base station 1004) may, at 1016, transmit, to the first UE 1002, first common communication setting parameters for the communication between the first UE and the network entity. The first common communication setting parameters may be based on multiple sets of first communication setup parameters (e.g., at 1012) respectively from multiple UEs (e.g., the first UE 1002 and the second UE 1006) including the first UE 1002. In some aspects, 1204 may be performed by the quantization and coding component 199.

At 1206, the network entity may receive, from the first UE, a processed gradient vector based on the first common communication setting parameters and the first gradient vector. For example, referring to FIG. 10, the network entity (e.g., base station 1004) may, at 1030, receive, from the first UE 1002, a processed gradient vector based on the first common communication setting parameters and the first gradient vector. In some aspects, 1206 may be performed by the quantization and coding component 199.

In some aspects, the first gradient vector and the processed gradient vector may be associated with an AI/ML model. The network entity may transmit, to the first UE, first model parameters for the AI/ML model, and the first gradient vector may be based on the first model parameters. For example, referring to FIG. 10, the first gradient vector (e.g., at 1010) and the processed gradient vector (e.g., at 1030) may be associated with an AI/ML model 1050. The network entity (e.g., base station 1004) may, at 1010, transmit, to the first UE 1002, first model parameters for the AI/ML model 1050, and the first gradient vector may be based on the first model parameters.

In some aspects, the network entity may aggregate multiple processed gradient vectors respectively from the multiple UEs to obtain an OTA summation of the processed gradient vectors; and transmit, to the first UE, second model parameters for the AI/ML model. The second model parameters may be based on the OTA summation of the processed gradient vectors. For example, referring to FIG. 10, the network entity (e.g., base station 1004) may aggregate multiple processed gradient vectors (e.g., received at 1030 and 1032) respectively from the multiple UEs (e.g., the first UE 1002 and the second UE 1006) to obtain an OTA summation of the processed gradient vectors (e.g., at 1034); and, at 1038, transmit to the first UE 1002 second model parameters for the AI/ML model 1050. The second model parameters may be based on the OTA summation of the processed gradient vectors.

In some aspects, the network entity may repeat a model update process for the AI/ML model based on the first common communication setting parameters and a current gradient vector. The model update process may include: receiving, from each UE of the multiple UEs, an updated gradient vector based on the first common communication setting parameters and the current gradient vector; aggregating the updated gradient vectors from the multiple UEs to obtain an updated OTA summation of the updated gradient vectors; and transmitting, to each UE of the multiple UEs, an update to current model parameters for the AI/ML model. The update to the current model parameters may be based on the updated OTA summation of the updated gradient vectors. For example, referring to FIG. 10, the network entity (e.g., base station 1004) may repeat (e.g., via 1044) a model update process for the AI/ML model 1050 based on the first common communication setting parameters and a current gradient vector. The model update process may include: receiving (e.g., at 1030 and 1032), from each UE of the multiple UEs (e.g., the first UE 1002 and the second UE 1006), an updated gradient vector based on the first common communication setting parameters and the current gradient vector; aggregating the updated gradient vectors from the multiple UEs to obtain an updated OTA summation of the updated gradient vectors (e.g., at 1034); and transmitting (e.g., at 1038), to each UE of the multiple UEs, an update to current model parameters for the AI/ML model. The update to the current model parameters may be based on the updated OTA summation of the updated gradient vectors.

In some aspects, the network entity may transmit, to the first UE, a termination signal for the model update process. For example, referring to FIG. 10, the network entity (e.g., base station 1004) may, at 1042, transmit, to the first UE 1002, a termination signal for the model update process.

In some aspects, the processed gradient vector may include a first number of gradients for the AI/ML model, and the available channel uses between the first UE and the network entity is a second number greater than the first number. In this case, the network entity may receive, from the first UE, additional values related to the processed gradient vector. For example, referring to FIG. 10, the processed gradient vector (e.g., at 1030) may include a first number (e.g., K) of gradients for the AI/ML model 1050, and the available channel uses between the first UE 1002 and the network entity (e.g., base station 1004) is a second number greater than the first number. In this case, the network entity may, at 1030, receive, from the first UE 1002, additional values related to the processed gradient vector. These additional values may help to reduce the distortion in the base station's estimation of the OTA summation of the UEs' gradients. For example, when K additional channel uses are available (i.e., N≥2K), the additional values may include the quantization error qⱼ that was introduced during the lattice quantization of xⱼ.

In some aspects, the first communication setup parameters may include model information and channel information. The model information may include one or more of: the maximum absolute value among gradients in the first gradient vector, or the gradient variance of the gradients in the first gradient vector. The channel information may include a noise variance for an AWGN associated with the channel between the first UE and the network entity. For example, referring to FIG. 10, the first communication setup parameters (e.g., at 1012) may include model information and channel information. The model information may include one or more of: the maximum absolute value among gradients in the first gradient vector (e.g., \hat{θ}ⱼ), or the gradient variance of the gradients in the first gradient vector (e.g., \hat{θ}ⱼ). The channel information may include a noise variance for an AWGN associated with the channel between the first UE 1002 and the network entity (e.g., base station 1004).

In some aspects, the first common communication setting parameters may include a common scaling factor, a common dithering seed, and a common scaled lattice structure for the lattice-based quantization and coding scheme, and the first common communication setting parameters may be applied to each UE of the multiple UEs. For example, referring to FIG. 10, the first common communication setting parameters may include a common scaling factor (e.g., β at 910), a common dithering seed (e.g., the seed to generate dⱼ at 920), and a common scaled lattice structure for the lattice-based quantization and coding scheme, and the first common communication setting parameters may be applied to each UE of the multiple UEs (e.g., the first UE 1002, the second UE 1006).

In some aspects, the first common communication setting parameters may include a lattice scaling factor, and the lattice scaling factor may be based on one or more of: an initial estimation of an SNR associated with the first UE and the network entity, or a channel state indicator. For example, referring to FIG. 10, the first common communication setting parameters (e.g., at 1016) may include a lattice scaling factor (e.g., α in Equation (9)), and the lattice scaling factor (e.g., α in Equation (9)) may be based on one or more of: an initial estimation of the SNR associated with the first UE 1002 and the network entity (e.g., base station 1004), or a channel state indicator.

In some aspects, the first common communication setting parameters may further include one or more of: an error scaling factor for scaling quantization errors based on a power constraint of the first UE, a basic lattice structure having dimensions of a first number for the lattice-based quantization and coding scheme, a lattice scaling factor associated with the basic lattice structure and the common scaled lattice structure, or a coding rate based on the first number and a number of channel uses associated with the first UE. For example, referring to FIG. 10, the first common communication setting parameters (e.g., at 1016) may further include one or more of: an error scaling factor for scaling quantization errors based on a power constraint of the first UE, a basic lattice structure (e.g., Λ_{f} in Equation (9)) having dimensions of a first number for the lattice-based quantization and coding scheme, a lattice scaling factor (e.g., α in Equation (9)) associated with the basic lattice structure and the common scaled lattice structure, or a coding rate (e.g., K/N) based on the first number (e.g., K) and a number of channel uses (e.g., N) associated with the first UE.

In some aspects, the network entity may transmit, to the first UE, an update request to update all or a subset of the first common communication setting parameters periodically. For example, referring to FIG. 10, the network entity (e.g., base station 1004) may, at 1018, transmit, to the first UE 1002, an update request to update all or a subset of the first common communication setting parameters periodically. In some aspects, the update request may be based on one or more of: a first change to an initial estimation of an SNR associated with the network entity and the first UE, or a second change to a channel state indicator. For example, referring to FIG. 10, the update request (e.g., at 1018) may be based on one or more of: the change to an initial estimation of an SNR associated with the network entity (e.g., base station 1004) and the first UE 1002, or the change to a channel state indicator.

In some aspects, the update request may include one or more of: a first update to the common lattice scaling factor, a second update to the error scaling factor, or a third update to the coding rate (e.g., K/N).

FIG. 13 is a diagram 1300 illustrating an example of a hardware implementation for an apparatus 1304. The apparatus 1304 may be a UE, a component of a UE, or may implement UE functionality. In some aspects, the apparatus 1304 may include at least one cellular baseband processor (or processing circuitry) 1324 (also referred to as a modem) coupled to one or more transceivers 1322 (e.g., cellular RF transceiver). The cellular baseband processor(s) (or processing circuitry) 1324 may include at least one on-chip memory (or memory circuitry) 1324′. In some aspects, the apparatus 1304 may further include one or more subscriber identity modules (SIM) cards 1320 and at least one application processor (or processing circuitry) 1306 coupled to a secure digital (SD) card 1308 and a screen 1310. The application processor(s) (or processing circuitry) 1306 may include on-chip memory (or memory circuitry) 1306′. In some aspects, the apparatus 1304 may further include a Bluetooth module 1312, a WLAN module 1314, an SPS module 1316 (e.g., GNSS module), one or more sensor modules 1318 (e.g., barometric pressure sensor/altimeter; motion sensor such as inertial measurement unit (IMU), gyroscope, and/or accelerometer(s); light detection and ranging (LIDAR), radio assisted detection and ranging (RADAR), sound navigation and ranging (SONAR), magnetometer, audio and/or other technologies used for positioning), additional memory modules 1326, a power supply 1330, and/or a camera 1332. The Bluetooth module 1312, the WLAN module 1314, and the SPS module 1316 may include an on-chip transceiver (TRX) (or in some cases, just a receiver (RX)). The Bluetooth module 1312, the WLAN module 1314, and the SPS module 1316 may include their own dedicated antennas and/or utilize the antennas 1380 for communication. The cellular baseband processor(s) (or processing circuitry) 1324 communicates through the transceiver(s) 1322 via one or more antennas 1380 with the UE 104 and/or with an RU associated with a network entity 1302. The cellular baseband processor(s) (or processing circuitry) 1324 and the application processor(s) (or processing circuitry) 1306 may each include a computer-readable medium/memory (or memory circuitry) 1324′, 1306′, respectively. The additional memory modules 1326 may also be considered a computer-readable medium/memory (or memory circuitry). Each computer-readable medium/memory (or memory circuitry) 1324′, 1306′, 1326 may be non-transitory. The cellular baseband processor(s) (or processing circuitry) 1324 and the application processor(s) (or processing circuitry) 1306 are each responsible for general processing, including the execution of software stored on the computer-readable medium/memory (or memory circuitry). The software, when executed by the cellular baseband processor(s) (or processing circuitry) 1324/application processor(s) (or processing circuitry) 1306, causes the cellular baseband processor(s) (or processing circuitry) 1324/application processor(s) (or processing circuitry) 1306 to perform the various functions described supra. The cellular baseband processor(s) (or processing circuitry) 1324 and the application processor(s) (or processing circuitry) 1306 are configured to perform the various functions described supra based at least in part of the information stored in the memory (or memory circuitry). That is, the cellular baseband processor(s) (or processing circuitry) 1324 and the application processor(s) (or processing circuitry) 1306 may be configured to perform a first subset of the various functions described supra without information stored in the memory and may be configured to perform a second subset of the various functions described supra based on the information stored in the memory. The computer-readable medium/memory (or memory circuitry) may also be used for storing data that is manipulated by the cellular baseband processor(s) (or processing circuitry) 1324/application processor(s) (or processing circuitry) 1306 when executing software. The cellular baseband processor(s) (or processing circuitry) 1324/application processor(s) (or processing circuitry) 1306 may be a component of the UE 350 and may include the at least one memory 360 and/or at least one of the TX processor 368, the RX processor 356, and the controller/processor 359. In one configuration, the apparatus 1304 may be at least one processor chip (modem and/or application) and include just the cellular baseband processor(s) (or processing circuitry) 1324 and/or the application processor(s) (or processing circuitry) 1306, and in another configuration, the apparatus 1304 may be the entire UE (e.g., see UE 350 of FIG. 3) and include the additional modules of the apparatus 1304.

As discussed supra, the component 198 may be configured to transmit, to a network entity based on a first gradient vector, first communication setup parameters for a lattice-based quantization and coding scheme for communication between the first UE and the network entity; receive, from the network entity, first common communication setting parameters for the communication between the first UE and the network entity, where the first common communication setting parameters are based on multiple sets of first communication setup parameters respectively from multiple UEs including the first UE; and transmit, to the network entity, a processed gradient vector based on the first common communication setting parameters and the first gradient vector. The component 198 may be further configured to perform any of the aspects described in connection with the flowchart in FIG. 11, and/or performed by the UE 1002 in FIG. 10. The component 198 may be within the cellular baseband processor(s) (or processing circuitry) 1324, the application processor(s) (or processing circuitry) 1306, or both the cellular baseband processor(s) (or processing circuitry) 1324 and the application processor(s) (or processing circuitry) 1306. The component 198 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. As shown, the apparatus 1304 may include a variety of components configured for various functions. In one configuration, the apparatus 1304, and in particular the cellular baseband processor(s) (or processing circuitry) 1324 and/or the application processor(s) (or processing circuitry) 1306, includes means for transmitting, to a network entity based on a first gradient vector, first communication setup parameters for a lattice-based quantization and coding scheme for communication between the first UE and the network entity; means for receiving, from the network entity, first common communication setting parameters for the communication between the first UE and the network entity, where the first common communication setting parameters are based on multiple sets of first communication setup parameters respectively from multiple UEs including the first UE; and means for transmitting, to the network entity, a processed gradient vector based on the first common communication setting parameters and the first gradient vector. The apparatus 1304 may further include means for performing any of the aspects described in connection with the flowchart in FIG. 11, and/or aspects performed by the UE 1002 in FIG. 10. The means may be the component 198 of the apparatus 1304 configured to perform the functions recited by the means. As described supra, the apparatus 1304 may include the TX processor 368, the RX processor 356, and the controller/processor 359. As such, in one configuration, the means may be the TX processor 368, the RX processor 356, and/or the controller/processor 359 configured to perform the functions recited by the means.

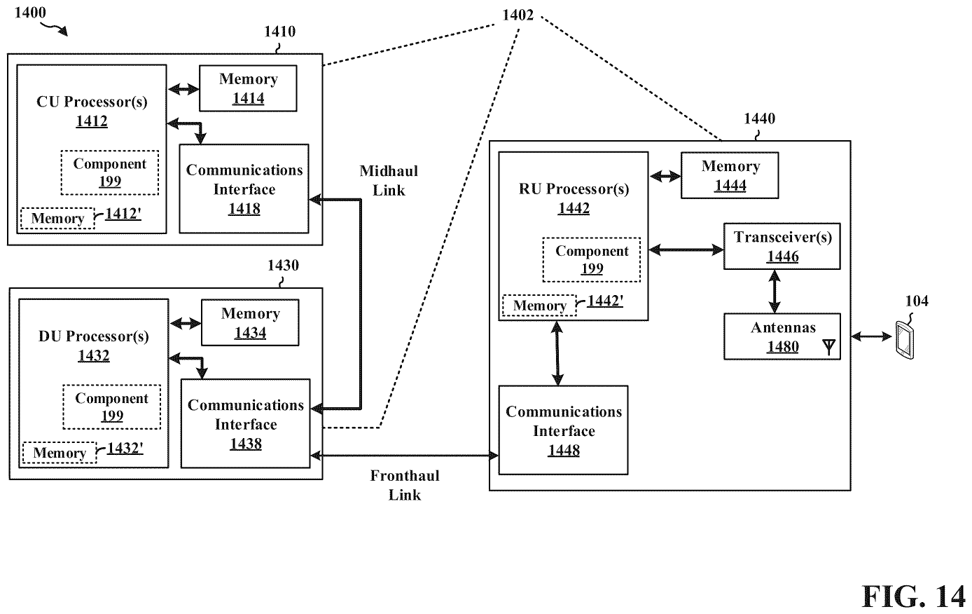

FIG. 14 is a diagram 1400 illustrating an example of a hardware implementation for a network entity 1402. The network entity 1402 may be a BS, a component of a BS, or may implement BS functionality. The network entity 1402 may include at least one of a CU 1410, a DU 1430, or an RU 1440. For example, depending on the layer functionality handled by the component 199, the network entity 1402 may include the CU 1410; both the CU 1410 and the DU 1430; each of the CU 1410, the DU 1430, and the RU 1440; the DU 1430; both the DU 1430 and the RU 1440; or the RU 1440. The CU 1410 may include at least one CU processor (or processing circuitry) 1412. The CU processor(s) (or processing circuitry) 1412 may include on-chip memory (or memory circuitry) 1412′. In some aspects, the CU 1410 may further include additional memory modules 1414 and a communications interface 1418. The CU 1410 communicates with the DU 1430 through a midhaul link, such as an F1 interface. The DU 1430 may include at least one DU processor (or processing circuitry) 1432. The DU processor(s) (or processing circuitry) 1432 may include on-chip memory (or memory circuitry) 1432′. In some aspects, the DU 1430 may further include additional memory modules 1434 and a communications interface 1438. The DU 1430 communicates with the RU 1440 through a fronthaul link. The RU 1440 may include at least one RU processor (or processing circuitry) 1442. The RU processor(s) (or processing circuitry) 1442 may include on-chip memory (or memory circuitry) 1442′. In some aspects, the RU 1440 may further include additional memory modules 1444, one or more transceivers 1446, antennas 1480, and a communications interface 1448. The RU 1440 communicates with the UE 104. The on-chip memory (or memory circuitry) 1412′, 1432′, 1442′ and the additional memory modules 1414, 1434, 1444 may each be considered a computer-readable medium/memory (or memory circuitry). Each computer-readable medium/memory (or memory circuitry) may be non-transitory. Each of the processors (or processing circuitry) 1412, 1432, 1442 is responsible for general processing, including the execution of software stored on the computer-readable medium/memory (or memory circuitry). The software, when executed by the corresponding processor(s) (or processing circuitry) causes the processor(s) (or processing circuitry) to perform the various functions described supra. The computer-readable medium/memory (or memory circuitry) may also be used for storing data that is manipulated by the processor(s) (or processing circuitry) when executing software.

As discussed supra, the component 199 may be configured to receive, from a first UE of multiple UEs, first communication setup parameters for a lattice-based quantization and coding scheme for communication between the first UE and the network entity, where the first communication setup parameters are based on a first gradient vector; transmit, to the first UE, first common communication setting parameters for the communication between the first UE and the network entity, where the first common communication setting parameters are based on multiple sets of first communication setup parameters respectively from multiple UEs including the first UE; and receive, from the first UE, a processed gradient vector based on the first common communication setting parameters and the first gradient vector. The component 199 may be further configured to perform any of the aspects described in connection with the flowchart in FIG. 12, and/or performed by the base station 1004 in FIG. 10. The component 199 may be within one or more processors (or processing circuitry) of one or more of the CU 1410, DU 1430, and the RU 1440. The component 199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. The network entity 1402 may include a variety of components configured for various functions. In one configuration, the network entity 1402 includes means for receiving, from a first UE of multiple UEs, first communication setup parameters for a lattice-based quantization and coding scheme for communication between the first UE and the network entity, where the first communication setup parameters are based on a first gradient vector; means for transmitting, to the first UE, first common communication setting parameters for the communication between the first UE and the network entity, where the first common communication setting parameters are based on multiple sets of first communication setup parameters respectively from multiple UEs including the first UE; and means for receiving, from the first UE, a processed gradient vector based on the first common communication setting parameters and the first gradient vector. The network entity 1402 may further include means for performing any of the aspects described in connection with the flowchart in FIG. 12, and/or aspects performed by the base station 1004 in FIG. 10. The means may be the component 199 of the network entity 1402 configured to perform the functions recited by the means. As described supra, the network entity 1402 may include the TX processor 316, the RX processor 370, and the controller/processor 375. As such, in one configuration, the means may be the TX processor 316, the RX processor 370, and/or the controller/processor 375 configured to perform the functions recited by the means.

This disclosure provides a method for wireless communication at a UE. The method may include transmitting, to a network entity based on a first gradient vector, first communication setup parameters for a lattice-based quantization and coding scheme for communication between the first UE and the network entity; receiving, from the network entity, first common communication setting parameters for the communication between the first UE and the network entity, where the first common communication setting parameters are based on multiple sets of first communication setup parameters respectively from multiple UEs including the first UE; and transmitting, to the network entity, a processed gradient vector based on the first common communication setting parameters and the first gradient vector. By introducing lattice-based quantization and coding into federated AI/ML OTA training in a coherent wireless communication scheme, the methods reduce the quantization error (distortion) during transmission of model parameters, resulting in more accurate aggregation at the base station and improved training convergence. Additionally, by dynamically adapting communication setting parameters (e.g., lattice scaling, code rates) based on channel conditions, the methods provide robustness and flexibility in varying wireless conditions, thereby improving the performance of wireless communication.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not limited to the aspects described herein, but are to be accorded the full scope consistent with the language claims. Reference to an element in the singular does not mean “one and only one” unless specifically so stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. Sets should be interpreted as a set of elements where the elements number one or more. Accordingly, for a set of X, X would include one or more elements. When at least one processor (i.e., a set of one or more processor P) is configured to perform a set of functions F, each processor of P may be configured to perform a subset S of F, where S S F. Accordingly, each processor of the at least one processor may be configured to perform a particular subset of the set of functions, where the subset is the full set, a proper subset of the set, or an empty subset of the set. A processor may be referred to as processor circuitry. A memory/memory module may be referred to as memory circuitry. If a first apparatus receives data from or transmits data to a second apparatus, the data may be received/transmitted directly between the first and second apparatuses, or indirectly between the first and second apparatuses through a set of apparatuses. A device configured to “output” data or “provide” data, such as a transmission, signal, or message, may transmit the data, for example with a transceiver, or may send the data to a device that transmits the data. A device configured to “obtain” data, such as a transmission, signal, or message, may receive, for example with a transceiver, or may obtain the data from a device that receives the data. Information stored in a memory includes instructions and/or data. All structural and functional equivalents to the elements of the various aspects described throughout this disclosure that are known or later come to be known to those of ordinary skill in the art are expressly incorporated herein by reference and are encompassed by the claims. Moreover, nothing disclosed herein is dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

The following aspects are illustrative only and may be combined with other aspects or teachings described herein, without limitation.

Aspect 1 is a method of wireless communication at a first user equipment (UE). The method includes transmitting, to a network entity based on a first gradient vector, first communication setup parameters for a lattice-based quantization and coding scheme for communication between the first UE and the network entity; receiving, from the network entity, first common communication setting parameters for the communication between the first UE and the network entity, wherein the first common communication setting parameters are based on multiple sets of first communication setup parameters respectively from multiple UEs including the first UE; and transmitting, to the network entity, a processed gradient vector based on the first common communication setting parameters and the first gradient vector.

Aspect 2 is the method of aspect 1, wherein the first gradient vector and the processed gradient vector are associated with an artificial intelligence/machine learning (AI/ML) model, and wherein the method further comprises receiving, from the network entity, first model parameters for the AI/ML model, wherein the first gradient vector is based on the first model parameters.

Aspect 3 is the method of aspect 2, wherein the method further comprises receiving, from the network entity, second model parameters for the AI/ML model, wherein the second model parameters are based on an aggregation of multiple processed gradient vectors respectively from the multiple UEs; and determining a second gradient vector based on the second model parameters.

Aspect 4 is the method of any of aspects 2 to 3, wherein the method further comprises repeating a model update process for the AI/ML model based on first common communication setting parameters and a current gradient vector, wherein the model update process includes transmitting, to the network entity, an updated gradient vector based on the first common communication setting parameters and the current gradient vector; receiving, from the network entity, an update to current model parameters for the AI/ML model, wherein the update to the current model parameters is based on an aggregation of multiple updated gradient vectors respectively from the multiple UEs; and updating the current gradient vector based on the update to the current model parameters.

Aspect 5 is the method of aspect 4, wherein the method further comprises receiving, from the network entity, a termination signal for the model update process; and terminating the model update process based on the termination signal.

Aspect 6 is the method of any of aspects 2 to 5, wherein the processed gradient vector includes a first number of gradients for the AI/ML model, and wherein an available channel uses between the first UE and the network entity is a second number greater than the first number, wherein the method further comprises transmitting, to the network entity, additional values related to the processed gradient vector.

Aspect 7 is the method of any of aspects 1 to 2, wherein the first communication setup parameters include model information and channel information, wherein the model information includes one or more of a maximum absolute value among gradients in the first gradient vector, or a gradient variance of the gradients in the first gradient vector, and wherein the channel information includes a noise variance for an additive white Gaussian noise (AWGN) associated with the channel between the first UE and the network entity.

Aspect 8 is the method of any of aspects 1 to 2, wherein the first common communication setting parameters include a common scaling factor, a common dithering seed, and a common scaled lattice structure for the lattice-based quantization and coding scheme, wherein the first common communication setting parameters is applied to each UE of the multiple UEs.

Aspect 9 is the method of aspect 8, wherein the first common communication setting parameters include a lattice scaling factor, and wherein the lattice scaling factor is based on one or more of an initial estimation of a signal-to-noise ratio (SNR) associated with the first UE and the network entity, or a channel state indicator.

Aspect 10 is the method of aspect 8, wherein the method further comprises applying the common scaling factor on the first gradient vector based on a power constraint of the first UE to obtain a scaled gradient vector; applying a dithering vector to the scaled gradient vector to obtain a dithered vector, wherein the dithering vector is based on the common dithering seed; and performing, based on the common scaled lattice structure, a quantization process on the dithered vector to obtain the processed gradient vector.

Aspect 11 is the method of aspect 10, wherein the method further comprises initiating, based on the common dithering seed, a random generator; and generating the dithering vector based on the random generator.

Aspect 12 is the method of aspect 8, wherein the first common communication setting parameters further include one or more of an error scaling factor for scaling quantization errors based on a power constraint of the first UE, a basic lattice structure having dimensions of a first number for the lattice-based quantization and coding scheme, a lattice scaling factor associated with the basic lattice structure and the common scaled lattice structure, or a coding rate based on the first number and a number of channel uses associated with the first UE.

Aspect 13 is the method of aspect 12, wherein the method further comprises receiving, from the network entity, an update request to update all or a subset of the first common communication setting parameters periodically.

Aspect 14 is the method of aspect 13, wherein the update request is based on one or more of a first change to an initial estimation of a signal-to-noise ratio (SNR) associated with the network entity and the first UE, or a second change to a channel state indicator.

Aspect 15 is the method of aspect 13, wherein the update request includes one or more of a first update to the common lattice scaling factor, a second update to the error scaling factor, or a third update to the coding rate.

Aspect 16 is an apparatus for wireless communication at a first UE, comprising: at least one memory; and at least one processor coupled to the at least one memory, the at least one processor is configured to perform the method of any of aspects 1 to 15.

Aspect 17 is the apparatus for wireless communication at a first UE, comprising means for performing each step in the method of any of aspects 1-15.

Aspect 18 is an apparatus of any of aspects 16-17, further comprising a transceiver configured to receive or to transmit in association with the method of any of aspects 1-15.

Aspect 19 is a computer-readable medium (e.g., a non-transitory computer-readable medium) storing computer executable code at a first UE, the code when executed by at least one processor causes the at least one processor to perform the method of any of aspects 1-15.

Aspect 20 is a method of wireless communication at a network entity. The method includes receiving, from a first user equipment (UE) of multiple UEs, first communication setup parameters for a lattice-based quantization and coding scheme for communication between the first UE and the network entity, wherein the first communication setup parameters are based on a first gradient vector; transmitting, to the first UE, first common communication setting parameters for the communication between the first UE and the network entity, wherein the first common communication setting parameters are based on multiple sets of first communication setup parameters respectively from multiple UEs including the first UE; and receiving, from the first UE, a processed gradient vector based on the first common communication setting parameters and the first gradient vector.

Aspect 21 is the method of aspect 20, wherein the first gradient vector and the processed gradient vector are associated with an artificial intelligence/machine learning (AI/ML) model, and wherein the method further comprises transmitting, to the first UE, first model parameters for the AI/ML model, wherein the first gradient vector is based on the first model parameters.

Aspect 22 is the method of aspect 21, wherein the method further comprises aggregating multiple processed gradient vectors respectively from the multiple UEs to obtain an over-the-air (OTA) summation of the processed gradient vectors; transmitting, to the first UE, second model parameters for the AI/ML model, wherein the second model parameters are based on the OTA summation of the processed gradient vectors.

Aspect 23 is the method of aspect 22, wherein the method further comprises repeating a model update process for the AI/ML model based on the first common communication setting parameters and a current gradient vector, wherein the model update process includes receiving, from each UE of the multiple UEs, an updated gradient vector based on the first common communication setting parameters and the current gradient vector; aggregating the updated gradient vectors from the multiple UEs to obtain an updated OTA summation of the updated gradient vectors; transmitting, to each UE of the multiple UEs, an update to current model parameters for the AI/ML model, wherein the update to the current model parameters is based on the updated OTA summation of the updated gradient vectors.

Aspect 24 is the method of aspect 23, wherein the method further comprises transmitting, to the first UE, a termination signal for the model update process.

Aspect 25 is the method of any of aspects 21 to 24, wherein the processed gradient vector includes a first number of gradients for the AI/ML model, and wherein an available channel uses between the first UE and the network entity is a second number greater than the first number, wherein the method further comprises receiving, from the first UE, additional values related to the processed gradient vector.

Aspect 26 is the method of any of aspects 21 to 25, wherein the first communication setup parameters include model information and channel information, wherein the model information includes one or more of a maximum absolute value among gradients in the first gradient vector, or a gradient variance of the gradients in the first gradient vector, and wherein the channel information includes a noise variance for an additive white Gaussian noise (AWGN) associated with the channel between the first UE and the network entity.

Aspect 27 is the method of any of aspects 21 to 25, wherein the first common communication setting parameters include a common scaling factor, a common dithering seed, and a common scaled lattice structure for the lattice-based quantization and coding scheme, wherein the first common communication setting parameters is applied to each UE of the multiple UEs.

Aspect 28 is the method of aspect 27, wherein the first common communication setting parameters include a lattice scaling factor, and wherein the lattice scaling factor is based on one or more of an initial estimation of a signal-to-noise ratio (SNR) associated with the first UE and the network entity, or a channel state indicator.

Aspect 29 is the method of aspect 27, wherein the first common communication setting parameters further include one or more of an error scaling factor for scaling quantization errors based on a power constraint of the first UE, a basic lattice structure having dimensions of a first number for the lattice-based quantization and coding scheme, a lattice scaling factor associated with the basic lattice structure and the common scaled lattice structure, or a coding rate based on the first number and a number of channel uses associated with the first UE.

Aspect 30 is the method of aspect 29, wherein the method further comprises transmitting, to the first UE, an update request to update all or a subset of the first common communication setting parameters periodically.

Aspect 31 is the method of aspect 30, wherein the update request is based on one or more of a first change to an initial estimation of a signal-to-noise ratio (SNR) associated with the network entity and the first UE, or a second change to a channel state indicator.

Aspect 32 is the method of aspect 30, wherein the update request includes one or more of a first update to the common lattice scaling factor, a second update to the error scaling factor, or a third update to the coding rate.

Aspect 33 is an apparatus for wireless communication at a network entity, comprising: at least one memory; and at least one processor coupled to the at least one memory and, where the at least one processor is configured to perform the method of any of aspects 20-32.

Aspect 34 is the apparatus for wireless communication at a network entity, comprising means for performing each step in the method of any of aspects 20-32.

Aspect 35 is an apparatus of any of aspects 33-34, further comprising a transceiver configured to receive or to transmit in association with the method of any of aspects 20-32.

Aspect 36 is a computer-readable medium (e.g., a non-transitory computer-readable medium) storing computer executable code at a network entity, the code when executed by at least one processor causes the at least one processor to perform the method of any of aspects 20-32.

What is claimed is:

1. An apparatus for wireless communication at a first user equipment (UE), comprising:
at least one memory; and
at least one processor coupled to the at least one memory and, based at least in part on information stored in the at least one memory, the at least one processor is configured to:
transmit, to a network entity based on a first gradient vector, first communication setup parameters for a lattice-based quantization and coding scheme for communication between the first UE and the network entity;
receive, from the network entity, first common communication setting parameters for the communication between the first UE and the network entity, wherein the first common communication setting parameters are based on multiple sets of first communication setup parameters respectively from multiple UEs including the first UE; and
transmit, to the network entity, a processed gradient vector based on the first common communication setting parameters and the first gradient vector.

2. The apparatus of claim 1, further comprising a transceiver coupled to the at least one processor, wherein to transmit the first communication setup parameters, the at least one processor is configured to transmit the first communication setup parameters via the transceiver, wherein the first gradient vector and the processed gradient vector are associated with an artificial intelligence/machine learning (AI/ML) model, and wherein the at least one processor is further configured to:
receive, from the network entity, first model parameters for the AI/ML model, wherein the first gradient vector is based on the first model parameters.

3. The apparatus of claim 2, wherein the at least one processor is further configured to:
receive, from the network entity, second model parameters for the AJ/ML model, wherein the second model parameters are based on an aggregation of multiple processed gradient vectors respectively from the multiple UEs; and
determine a second gradient vector based on the second model parameters.

4. The apparatus of claim 3, wherein the at least one processor is further configured to:
repeat a model update process for the AI/ML model based on the first common communication setting parameters and a current gradient vector, wherein the model update process includes:
transmitting, to the network entity, an updated gradient vector based on the first common communication setting parameters and the current gradient vector;
receiving, from the network entity, an update to current model parameters for the AI/ML model, wherein the update to the current model parameters is based on an additional aggregation of multiple updated gradient vectors respectively from the multiple UEs; and
updating the current gradient vector based on the update to the current model parameters.

5. The apparatus of claim 4, wherein the at least one processor is further configured to:
receive, from the network entity, a termination signal for the model update process; and
terminate the model update process based on the termination signal.

6. The apparatus of claim 2, wherein the processed gradient vector includes a first number of gradients for the AI/ML model, and wherein an available channel uses between the first UE and the network entity is a second number greater than the first number, and wherein the at least one processor is further configured to:
transmit, to the network entity, additional values related to the processed gradient vector.

7. The apparatus of claim 2, wherein the first communication setup parameters include model information and channel information, wherein the model information includes one or more of:
a maximum absolute value among gradients in the first gradient vector, or
a gradient variance of the gradients in the first gradient vector, and wherein the channel information includes a noise variance for an additive white Gaussian noise (AWGN) associated with a channel between the first UE and the network entity.

8. The apparatus of claim 2, wherein the first common communication setting parameters include a common scaling factor, a common dithering seed, and a common scaled lattice structure for the lattice-based quantization and coding scheme, wherein the first common communication setting parameters is applied to each UE of the multiple UEs.

9. The apparatus of claim 8, wherein the first common communication setting parameters include a lattice scaling factor, and wherein the lattice scaling factor is based on one or more of:
an initial estimation of a signal-to-noise ratio (SNR) associated with the first UE and the network entity, or
a channel state indicator.

10. The apparatus of claim 8, wherein the at least one processor is further configured to:
apply the common scaling factor on the first gradient vector based on a power constraint of the first UE to obtain a scaled gradient vector;
apply a dithering vector to the scaled gradient vector to obtain a dithered vector, wherein the dithering vector is based on the common dithering seed; and
perform, based on the common scaled lattice structure, a quantization process on the dithered vector to obtain the processed gradient vector.

11. The apparatus of claim 10, wherein the at least one processor is further configured to:
initiate, based on the common dithering seed, a random generator; and
generate the dithering vector based on the random generator.

12. The apparatus of claim 8, wherein the first common communication setting parameters further include one or more of:
an error scaling factor for scaling quantization errors based on a power constraint of the first UE,
a basic lattice structure having dimensions of a first number for the lattice-based quantization and coding scheme,
a lattice scaling factor associated with the basic lattice structure and the common scaled lattice structure, or
a coding rate based on the first number and a number of channel uses associated with the first UE.

13. The apparatus of claim 12, wherein the at least one processor is further configured to:
receive, from the network entity, an update request to update all or a subset of the first common communication setting parameters periodically.

14. The apparatus of claim 13, wherein the update request is based on one or more of:
a first change to an initial estimation of a signal-to-noise ratio (SNR) associated with the network entity and the first UE, or
a second change to a channel state indicator.

15. The apparatus of claim 13, wherein the update request includes one or more of:
a first update to the lattice scaling factor,
a second update to the error scaling factor, or
a third update to the coding rate.

16. An apparatus for wireless communication at a network entity, comprising:
at least one memory; and
at least one processor coupled to the at least one memory and, based at least in part on information stored in the at least one memory, the at least one processor is configured to:
receive, from a first user equipment (UE) of multiple UEs, first communication setup parameters for a lattice-based quantization and coding scheme for communication between the first UE and the network entity, wherein the first communication setup parameters are based on a first gradient vector;
transmit, to the first UE, first common communication setting parameters for the communication between the first UE and the network entity, wherein the first common communication setting parameters are based on multiple sets of first communication setup parameters respectively from the multiple UEs including the first UE; and
receive, from the first UE, a processed gradient vector based on the first common communication setting parameters and the first gradient vector.

17. The apparatus of claim 16, further comprising a transceiver coupled to the at least one processor, wherein to receive the first communication setup parameters, the at least one processor is configured to receive the first communication setup parameters via the transceiver, wherein the first gradient vector and the processed gradient vector are associated with an artificial intelligence/machine learning (AI/ML) model, and wherein the at least one processor is further configured to:
transmit, to the first UE, first model parameters for the AI/ML model, wherein the first gradient vector is based on the first model parameters.

18. The apparatus of claim 17, wherein the at least one processor is further configured to:
aggregate multiple processed gradient vectors respectively from the multiple UEs to obtain an over-the-air (OTA) summation of the multiple processed gradient vectors; and
transmit, to the first UE, second model parameters for the AJ/ML model, wherein the second model parameters are based on the OTA summation of the multiple processed gradient vectors.

19. The apparatus of claim 18, wherein the at least one processor is further configured to:
repeat a model update process for the AI/ML model based on the first common communication setting parameters and a current gradient vector, wherein the model update process includes:
receiving, from each UE of the multiple UEs, an updated gradient vector based on the first common communication setting parameters and the current gradient vector;
aggregating updated gradient vectors received from the multiple UEs to obtain an updated OTA summation of the updated gradient vectors; and
transmitting, to each UE of the multiple UEs, an update to current model parameters for the AI/ML model, wherein the update to the current model parameters is based on the updated OTA summation of the updated gradient vectors.

20. A method of wireless communication at a first user equipment (UE), comprising:
transmitting, to a network entity based on a first gradient vector, first communication setup parameters for a lattice-based quantization and coding scheme for communication between the first UE and the network entity;
receiving, from the network entity, first common communication setting parameters for the communication between the first UE and the network entity, wherein the first common communication setting parameters are based on multiple sets of first communication setup parameters respectively from multiple UEs including the first UE; and
transmitting, to the network entity, a processed gradient vector based on the first common communication setting parameters and the first gradient vector.
